(19) United States
(12) Patent Application Publication
(10) Pub. No.: US 2016/0247972 A1
(43) Pub. Date: Aug. 25, 2016

(54) LIGHT-EMITTING DIODE CHIP

(71) Applicant: Genesis Photonics Inc., Tainan City (TW)

(72) Inventors: Yu-Chen Kuo, Tainan City (TW); Teng-Hsien Lai, Tainan City (TW); Kai-Shun Kang, Tainan City (TW); Yan-Ting Lan, Tainan City (TW); Jing-En Huang, Tainan City (TW)

(21) Appl. No.: 15/045,263

(22) Filed: Feb. 17, 2016

Related U.S. Application Data
(60) Provisional application No. 62/116,923, filed on Feb. 17, 2015.
(60) Provisional application No. 62/151,377, filed on Apr. 22, 2015.
(60) Provisional application No. 62/213,592, filed on Sep. 2, 2015.

(51) Int. Cl. H01L 33/38; H01L 33/06; H01L 33/40; H01L 33/14

(52) U.S. Cl. CPC H01L 33/387; H01L 33/145; H01L 33/06; H01L 33/40; H01L 2933/0016; H01L 33/005

(57) ABSTRACT

A light-emitting diode chip including a semiconductor device layer, a first electrode, a current-blocking layer, a current-spreading layer, and a second electrode is provided. The semiconductor device layer includes a first-type doped semiconductor layer, a second-type doped semiconductor layer, and a light-emitting layer located between the first-type and second-type doped semiconductor layers. The first electrode is electrically connected to the first-type doped semiconductor layer. The current-blocking layer is disposed on the second-type doped semiconductor layer, and the current-blocking layer includes a main body and an extension portion extended from the main body. The current-spreading layer covers the current-blocking layer. The second electrode is electrically connected to the second-type doped semiconductor layer via the current-spreading layer, wherein the second electrode includes a bonding pad and a finger portion extended from the bonding pad, the bonding pad is located above the main body, the finger portion is located above the extension portion, and a partial region of the finger portion does not overlap the extension portion.

### CROSS-REFERENCE TO RELATED APPLICATION

This application claims the priority benefits of U.S. provisional application Ser. No. 62/116,923, filed on Feb. 17, 2015, U.S. provisional application Ser. No. 62/151,377, filed on Apr. 22, 2015, and U.S. provisional application Ser. No. 62/213,592, filed on Sep. 2, 2015. The entirety of each of the above-mentioned patent applications is hereby incorporated by reference herein and made a part of this specification.

### BACKGROUND OF THE INVENTION

1. Field of the Invention

The invention relates to a light-emitting device, and more particularly, to a light-emitting diode (LED) chip.

2. Description of Related Art

With the advancement in semiconductor techniques, the current light-emitting diode now has characteristics such as high brightness and high color rendering properties. Moreover, the light-emitting diode has advantages such as power saving, small size, low voltage drive, and lack of mercury, and therefore the light-emitting diode is extensively applied in areas such as display and illumination. In general, the luminous efficiency of the light-emitting diode chip and the internal quantum efficiency (i.e., light-extraction efficiency) of the light-emitting diode chip are related. When the light emitted by the light-emitting layer has a greater ratio for passing through the light-emitting diode chip, the internal quantum efficiency of the light-emitting diode chip is better. The electrode of the light-emitting diode chip is generally made from a metal material, and due to the opacity of the metal material, the light emitted by the region covered by the electrode on the light-emitting diode chip cannot be effectively utilized. As a result, energy waste occurs. Therefore, a technique of manufacturing a current-blocking layer between an electrode and a semiconductor device layer has been developed. However, increasing the luminous efficiency of a light-emitting diode chip via the current-blocking layer still has much room for improvement. Therefore, how to further improve the luminous efficiency of the LED chip is a current focus for research and development personnel.

### SUMMARY OF THE INVENTION

The invention provides a light-emitting diode chip having a current-blocking layer so as to effectively control the location of current collection. As a result, luminous efficiency is effectively improved.

The invention provides a light-emitting diode chip including a semiconductor device layer, a first electrode, a current-blocking layer, a current-spreading layer, and a second electrode. The semiconductor device layer includes a first-type doped semiconductor layer, a light-emitting layer, and a second-type doped semiconductor layer, wherein the light-emitting layer is located between the first-type doped semiconductor layer and the second-type doped semiconductor layer. The first electrode is electrically connected to the first-type doped semiconductor layer. The current-blocking layer is disposed on the second-type doped semiconductor layer, and the current-blocking layer includes a main body and an extension portion extended from the main body. The current-spreading layer is disposed on the second-type doped semiconductor layer to cover the current-blocking layer. The second electrode is electrically connected to the second-type doped semiconductor layer, wherein the second electrode includes a bonding pad and a finger portion extended from the bonding pad, the finger portion is located above the extension portion, and a partial region of the finger portion does not overlap the extension portion.

The invention provides another light-emitting diode chip including a semiconductor device layer, a first electrode, a current-blocking layer, a current-spreading layer, and a second electrode. The semiconductor device layer includes a first-type doped semiconductor layer, a light-emitting layer, and a second-type doped semiconductor layer, wherein the light-emitting layer is located between the first-type doped semiconductor layer and the second-type doped semiconductor layer. The first electrode is electrically connected to the first-type doped semiconductor layer. The current-blocking layer is disposed on the second-type doped semiconductor layer. The current-blocking layer includes a main body and an extension portion extended from the main body. The current-spreading layer is disposed on the second-type doped semiconductor layer to cover the current-blocking layer. The second electrode is electrically connected to the second-type doped semiconductor layer via the current-spreading layer, wherein the second electrode includes a bonding pad and a finger portion extended from the bonding pad, the bonding pad is located above the main body, the finger portion is located above the extension portion, the bonding pad passes through the current-spreading layer and the main body, and the bonding pad is in contact with the second-type doped semiconductor layer.

The invention provides another light-emitting diode chip including a semiconductor device layer, a current-spreading layer, a first electrode, an insulating layer, and a second electrode. The semiconductor device layer includes a first-type doped semiconductor layer, a light-emitting layer, and a second-type doped semiconductor layer. The light-emitting layer is located between the first-type doped semiconductor layer and the second-type doped semiconductor layer. The current-spreading layer is disposed on the second-type doped semiconductor layer. The first electrode is electrically connected to the first-type doped semiconductor layer. The insulating layer is disposed between the first electrode and the first-type doped semiconductor layer. The second electrode is electrically connected to the second-type doped semiconductor layer via the current-spreading layer.

The invention provides another light-emitting diode chip including a semiconductor device layer, a first electrode, a second electrode, a current-blocking layer, and a current-spreading layer. The semiconductor device layer includes a first-type doped semiconductor layer, a light-emitting layer, and a second-type doped semiconductor layer. The light-emitting layer is located between the first-type doped semiconductor layer and the second-type doped semiconductor layer. The first electrode is electrically connected to the first-type doped semiconductor layer. The second electrode is electrically connected to the second-type doped semiconductor layer. The second electrode includes a bonding pad and a finger portion extended from the bonding pad. The current-blocking layer is disposed on the second-type doped semiconductor layer and disposed inside the range of the orthographic projection of the finger portion. The current-spreading layer is disposed on the second-type doped semiconductor layer to cover the current-blocking layer. The bonding pad passes through the current-spreading layer and the current-blocking layer, and the bonding pad is electrically in contact with the second-type doped semiconductor layer.

Based on the above, since in the invention, a current-blocking layer having a specific pattern design is adopted in the light-emitting diode chip, the light-emitting diode chip of the invention has good luminous efficiency.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1C are cross-sectional views of a light-emitting diode chip according to the invention.

FIG. 2A to FIG. 2E are top views of different light-emitting diode chips according to the first embodiment of the invention.

FIG. 3A to FIG. 3C are top views of different light-emitting diode chips according to the second embodiment of the invention.

FIG. 4A to FIG. 4B are cross-sectional views of different light-emitting diode chips according to the third embodiment of the invention.

FIG. 5A to FIG. 5D are flowcharts of the manufacturing method of the light-emitting diode chip of the embodiment of FIG. 4A.

FIG. 6A to FIG. 6B are top views of different light-emitting diode chips according to the fourth embodiment of the invention.

FIG. 7A is a top view of the light-emitting diode chip according to the fifth embodiment of the invention.

FIG. 7B is a cross-sectional view of the light-emitting diode chip of FIG. 7A along line A-A′.

FIG. 7C to FIG. 7F, FIG. 7G to FIG. 7J, and FIG. 7K to FIG. 7M are flowcharts of the manufacturing method of different light-emitting diode chips according to the sixth embodiment of the invention.

FIG. 8A is a top view of the light-emitting diode chip according to the seventh embodiment of the invention.

FIG. 8B is a cross-sectional view of the light-emitting diode chip of FIG. 8A along line B-B′.

FIG. 9A is a top view of the light-emitting diode chip according to the eighth embodiment of the invention.

FIG. 9B is a cross-sectional view of the light-emitting diode chip of FIG. 9A along line C-C′.

FIG. 10A is a top view of the light-emitting diode chip according to the ninth embodiment of the invention.

FIG. 10B is a cross-sectional view of the light-emitting diode chip of FIG. 10A along line D-D′.

FIG. 10C to FIG. 10F are flowcharts of the manufacturing method of the light-emitting diode chip of the embodiment of FIG. 10A.

FIG. 11A is a top view of the light-emitting diode chip according to the tenth embodiment of the invention.

FIG. 11B is a cross-sectional view of the light-emitting diode chip of FIG. 11A along line E-E′.

FIG. 12A is a top view of the light-emitting diode chip according to the eleventh embodiment of the invention.

FIG. 12B is a cross-sectional view of the light-emitting diode chip of FIG. 12A along line F-F′.

FIG. 13A is a top view of the light-emitting diode chip according to the twelfth embodiment of the invention.

FIG. 13B is a cross-sectional view of the light-emitting diode chip of FIG. 13A along line G-G′.

FIG. 14A is a top view of the light-emitting diode chip according to the thirteenth embodiment of the invention.

FIG. 14B is a cross-sectional view of the light-emitting diode chip of FIG. 14A along line H-H′.

FIG. 15A is a top view of the light-emitting diode chip according to the fourteenth embodiment of the invention.

FIG. 15B is a cross-sectional view of the light-emitting diode chip of FIG. 15A along line I-I′.

FIG. 16A is a top view of the light-emitting diode chip according to the fifteenth embodiment of the invention.

FIG. 16B is a cross-sectional view of the light-emitting diode chip of FIG. 16A along line J-J′.

FIG. 17A is a top view of the light-emitting diode chip according to the sixteenth embodiment of the invention.

FIG. 17B is a cross-sectional view of the light-emitting diode chip of FIG. 17A along line K-K′.

FIG. 18A is a top view of the light-emitting diode chip according to the seventeenth embodiment of the invention.

FIG. 18B is a cross-sectional view of the light-emitting diode chip of FIG. 18A along line L-L′.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

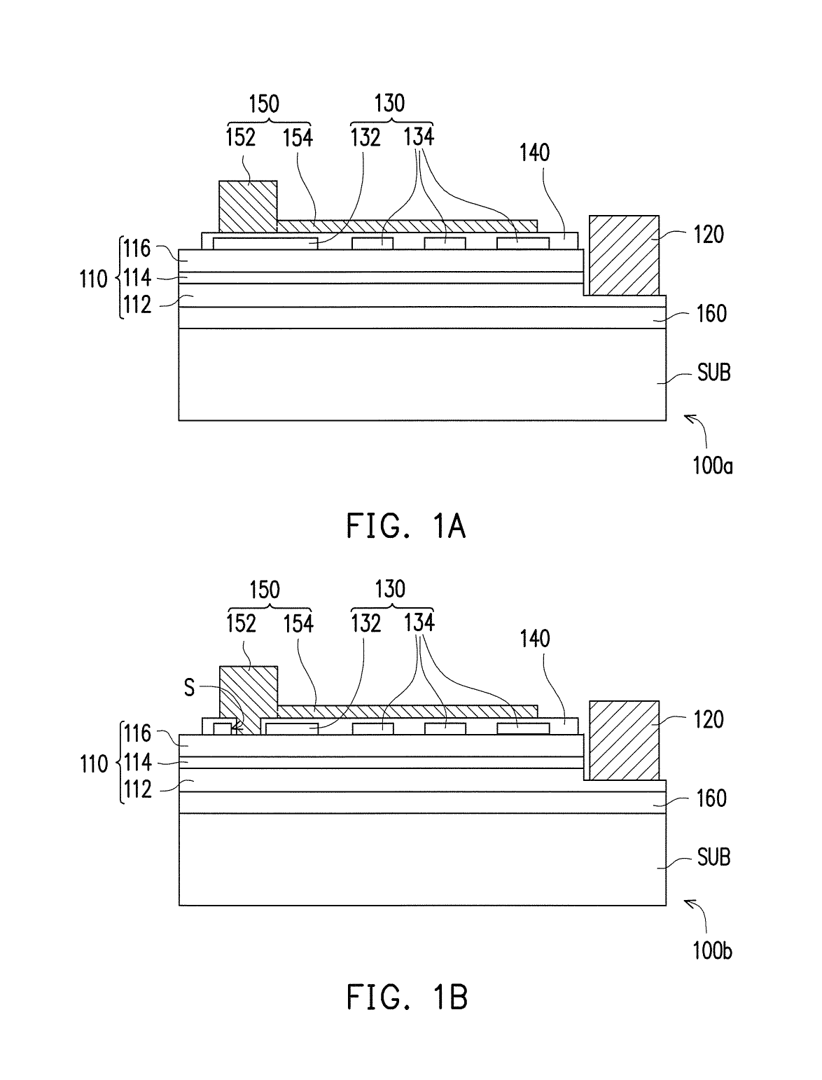

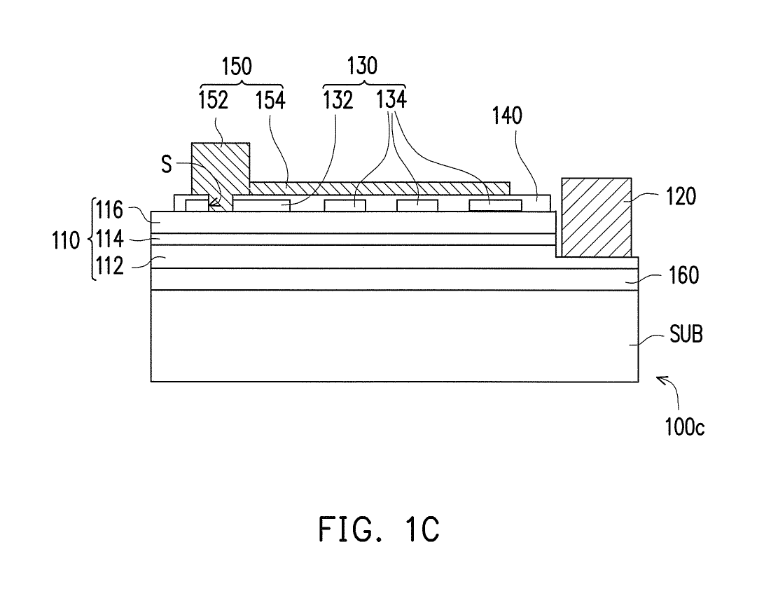

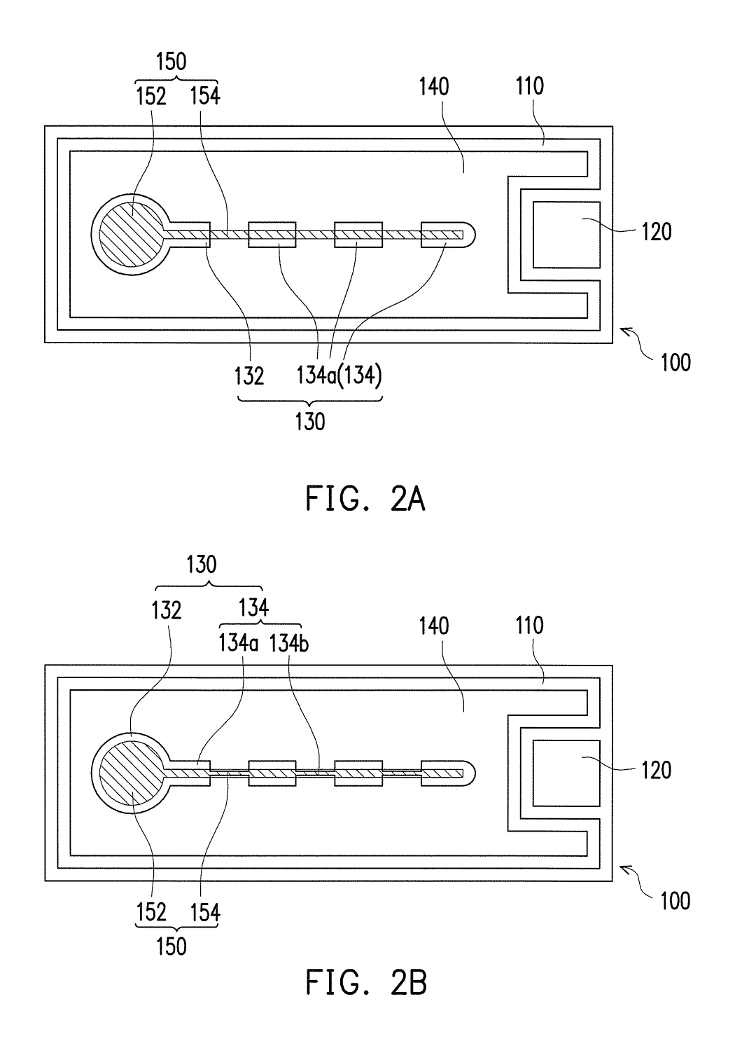

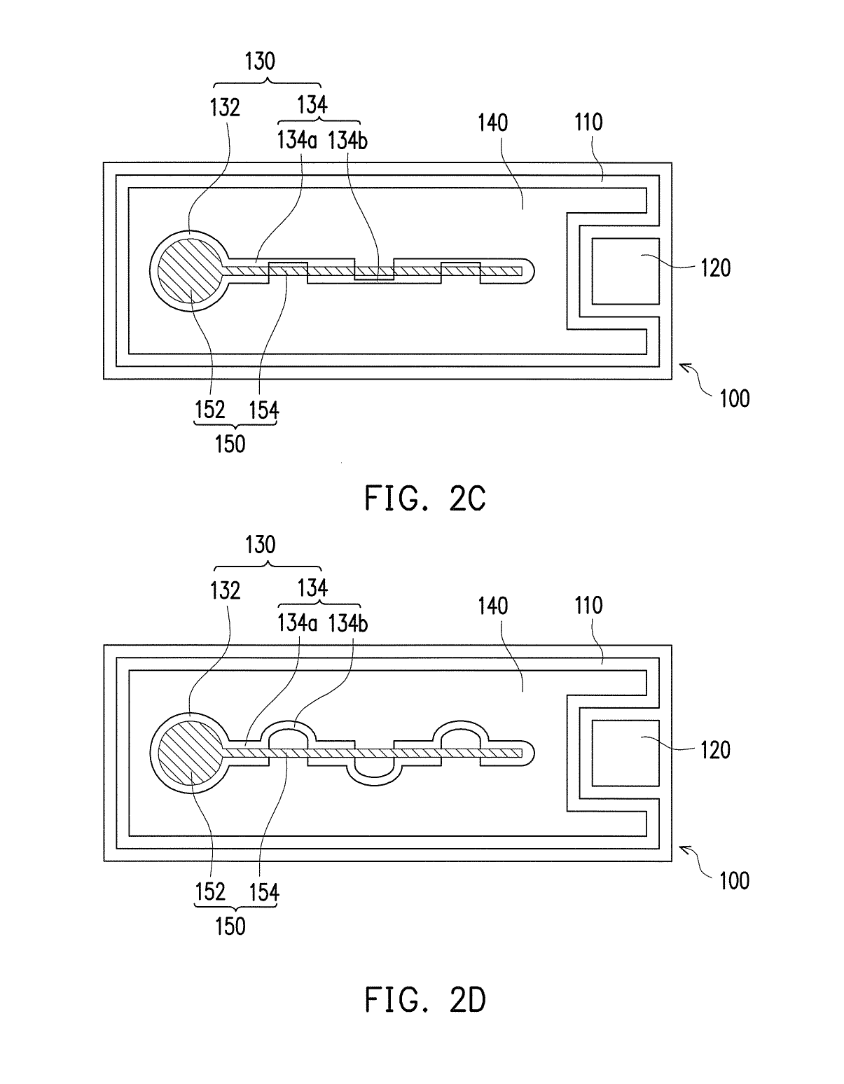

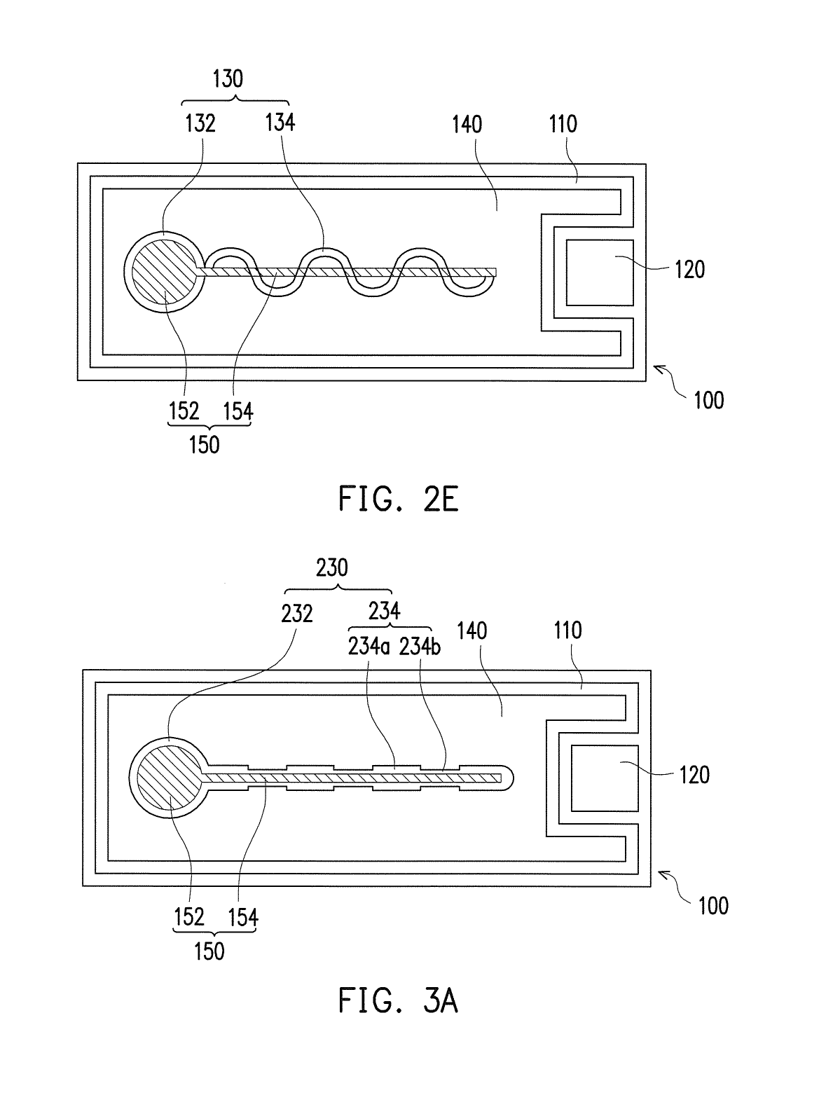

FIG. 1A to FIG. 1C are cross-sectional views of a light-emitting diode chip according to the invention, and FIG. 2A to FIG. 2E are top views of different light-emitting diode chips according to the first embodiment of the invention.

Referring to FIG. 1A, a light-emitting diode chip 100a of the present embodiment includes a semiconductor device layer 110, a first electrode 120, a current-blocking layer 130, a current-spreading layer 140, and a second electrode 150. The semiconductor device layer 110 includes a first-type doped semiconductor layer 112, a light-emitting layer 114, and a second-type doped semiconductor layer 116, wherein the light-emitting layer 114 is located between the first-type doped semiconductor layer 112 and the second-type doped semiconductor layer 116. The first electrode 120 is electrically connected to the first-type doped semiconductor layer 112. The current-blocking layer 130 is disposed on the second-type doped semiconductor layer 116, and the current-blocking layer 130 includes a main body 132 and an extension portion 134 extended from the main body 132. The current-spreading layer 140 is disposed on the second-type doped semiconductor layer 116 to cover the current-blocking layer 130. The second electrode 150 is electrically connected to the second-type doped semiconductor layer 116 via the current-spreading layer 140, wherein the second electrode 150 includes a bonding pad 152 and a finger portion 154 extended from the bonding pad 152, the bonding pad 152 is located above the main body 132, the finger portion 154 is located above the extension portion 134, and a partial region of the finger portion 154 does not overlap the extension portion 134.

Referring to FIG. 1B, the main difference between a light-emitting diode chip 100b in FIG. 1B and the light-emitting diode chip 100a of the above embodiment is: the bonding pad 152 passes through the current-spreading layer 140 and the main body 132, and the bonding pad 152 is in contact with the second-type doped semiconductor layer 116, wherein the current-spreading layer 140 covers a sidewall S of the main body 132 that the bonding pad 152 passes through.

Referring to FIG. 1C, the main difference between a light-emitting diode chip 100c in FIG. 1C and the light-emitting diode chip 100b of the above embodiment is: the current-spreading layer 140 does not cover the sidewall S of the main body 132 that the bonding pad 152 passes through. In other words, the bonding pad 152 passing through the current-spreading layer 140 and the main body 132 is directly in contact or connected with the sidewall S of the main body 132.

Since a partial region of the finger portion 154 does not overlap the extension portion 134 of the current-blocking layer 130, the driving current applied to the second electrode 150 can be readily transmitted to the semiconductor device layer 110 via the regions (i.e., current-collecting regions) not overlapping the extension portion 134. In other words, in the present embodiment, the location of the current-collecting regions in the light-emitting diode chip 100 can be controlled via the pattern designs of the extension portion 134 and the finger portion 154 and the overlapping condition of the two, so as to improve the luminous efficiency of the light-emitting diode chip 100.

In the present embodiment, the light-emitting layer 114 is disposed on the first-type doped semiconductor layer 112 to expose a portion of the first-type doped semiconductor layer 112, and the first electrode 120 is disposed on the portion of the first-type doped semiconductor layer 112 exposed by the light-emitting layer 114. In other words, the light-emitting diode chip 100 of the present embodiment is a horizontal-type light-emitting diode chip. For instance, the first-type doped semiconductor layer 112 in the semiconductor device layer 110 is, for instance, an N-type doped semiconductor layer, the second-type doped semiconductor layer 116 is, for instance, a P-type doped semiconductor layer, and the light-emitting layer 114 is, for instance, a multiple quantum well (MQW) formed by a plurality of alternately-stacked well layers and barrier layers. Moreover, the semiconductor device layer 110 of the present embodiment is, for instance, manufactured on a substrate SUB via an epitaxial process, and the substrate SUB can be, for instance, a sapphire substrate, a silicon substrate, or a silicon carbide substrate.

It should be mentioned that, the above semiconductor device layer 110 can further include a buffer layer 160, and the buffer layer 160 is generally formed on the substrate SUB before the manufacture of the first-type doped semiconductor layer 112. In other words, the buffer layer 160 can be optionally formed between the substrate SUB and the semiconductor device layer 110 to provide suitable stress relief and improve the epitaxial quality of a subsequently-formed thin film.

In the present embodiment, the first electrode 120 is, for instance, a metal material having good Ohmic contact with the first-type doped semiconductor layer 112, the material of the current-blocking layer 130 is, for instance, a dielectric layer, the material of the current-spreading layer 140 is, for instance, a transparent conducting material, and the second electrode 150 is, for instance, a metal material having good Ohmic contact with the current-spreading layer 140. For instance, the material of the first electrode 120 includes a conducting material such as chromium (Cr), gold (Au), aluminum (Al), or titanium (Ti), the material of the current-blocking layer 130 includes a dielectric material such as silicon oxide (SiOx) or silicon nitride (SiNx), the material of the current-spreading layer 140 includes a transparent conducting material such as indium-tin-oxide (ITO) or indium-zinc-oxide (IZO); and the material of the second electrode 150 includes a conducting material such as Cr, Au, Al, or Ti.

The current-blocking layer 130 of the present embodiment can adopt different designs, and in the following, different designs of the current-blocking layer 130 are described with reference to FIG. 2A to FIG. 2E.

As shown in FIG. 2A, the extension portion 134 of the present embodiment can include a plurality of current-blocking patterns 134a separated from one another, and the current-blocking patterns 134a are arranged along the extending direction of the finger portion 154. For instance, the current-blocking patterns 134a are block patterns. It can be known from FIG. 2A that, the current-blocking patterns 134a separated from one another can effectively block current from the finger portion 154, and regions between adjacent current-blocking patterns 134a can be regarded as regions of current collection. It should be mentioned that, the spacing between any two adjacent current-blocking patterns 134a can be suitably changed according to actual design requirements to adjust the size of the current-collecting regions.

As shown in FIG. 2B, the extension portion 134 of the present embodiment can include a plurality of current-blocking patterns 134a and a plurality of connecting patterns 134b arranged along the extending direction of the finger portion 154, wherein any two adjacent current-blocking patterns 134a are connected to each other via the corresponding connecting pattern 134b. The connecting patterns 134b partially overlap the finger portion 154, and the width of each of the connecting patterns 134b along the extending direction of the finger portion 154 is less than the width of the finger portion 154. For instance, the current-blocking patterns 134a are block patterns, and the connecting patterns 134b are stripe patterns. It can be known from FIG. 2B that, the above current-blocking patterns 134a can effectively block current from the finger portion 154, and since the connecting patterns 134b partially overlap the finger portion 154, the connecting patterns 134b can still partially block current from the finger portion 154, and the surrounding region of the connecting patterns 134b can be regarded as a region of current collection.

As shown in FIG. 2C, the extension portion 134 of the present embodiment can include a plurality of current-blocking patterns 134a and a plurality of connecting patterns 134b arranged along the extending direction of the finger portion 154, wherein any two adjacent current-blocking patterns 134a are connected to each other via the corresponding connecting pattern 134b. The connecting patterns 134b do not overlap the finger portion 154, and the width of each of the connecting patterns 134b along the extending direction of the finger portion 154 is less than the width of the finger portion 154. For instance, the current-blocking patterns 134a are block patterns, and the connecting patterns 134b are stripe patterns. It can be known from FIG. 2C that, the above current-blocking patterns 134a can effectively block current from the finger portion 154, and the blocking effect of the connecting patterns 134b against current from the finger portion 154 is less significant, and therefore the region between adjacent current-blocking patterns 134a can be regarded as a region of current collection.

As shown in FIG. 2D, the extension portion 134 of the present embodiment similarly can include a plurality of current-blocking patterns 134a and a plurality of connecting patterns 134b arranged along the extending direction of the finger portion 154, wherein any two adjacent current-blocking patterns 134a are connected to each other via the corresponding connecting pattern 134b. However, the connecting patterns 134b in FIG. 2C do not overlap the finger portion 154. For instance, the current-blocking patterns 134a are block patterns, and the connecting patterns 134b are arc patterns. It can be known from FIG. 2C that, the above current-blocking patterns 134a can effectively block current from the finger portion 154, and the blocking effect of the connecting patterns 134b against current from the finger portion 154 is less significant, and therefore the region between adjacent current-blocking patterns 134a can be regarded as a region of current collection.

As shown in FIG. 2E, the extension portion 134 of the present embodiment can be a wave pattern, and the wave pattern has a plurality of intersections with the finger portion 154. It should be mentioned that, at the intersections of the wave pattern and the finger portion 154, current from the finger portion 154 is not effectively blocked. However, at other locations of the finger portion 154, the blocking effect of the connecting patterns 134b against current from the finger portion 154 is less significant, and therefore except for the intersections of the wave pattern and the finger portion 154, the other locations can all be regarded as regions of current collection.

### Second Embodiment

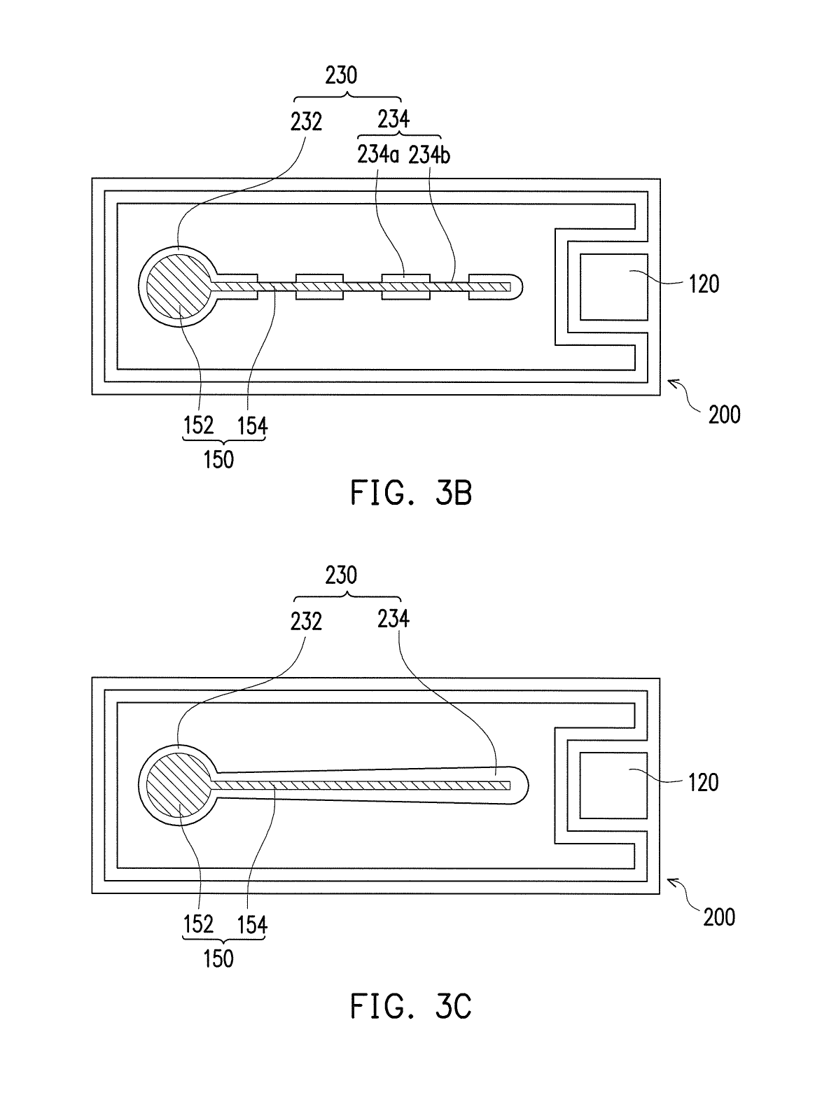

FIG. 3A to FIG. 3C are top views of different light-emitting diode chips according to the second embodiment of the invention. Referring to FIG. 1A to FIG. 1C and FIG. 3A, a light-emitting diode chip 200 of the present embodiment includes a semiconductor device layer 110, a first electrode 120, a current-blocking layer 230, a current-spreading layer 140, and a second electrode 150. The semiconductor device layer 110 includes a first-type doped semiconductor layer 112, a light-emitting layer 114, and a second-type doped semiconductor layer 116, wherein the light-emitting layer 114 is located between the first-type doped semiconductor layer 112 and the second-type doped semiconductor layer 116. The first electrode 120 is electrically connected to the first-type doped semiconductor layer 112. The current-blocking layer 230 includes a main body 232 and an extension portion 234 extended from the main body 232. The current-blocking layer 230 is disposed on the second-type doped semiconductor layer 116. The current-spreading layer 140 is disposed on the second-type doped semiconductor layer 116 to cover the current-blocking layer 230. The second electrode 10 is electrically connected to the second-type doped semiconductor layer 116 via the current-spreading layer 140, wherein the second electrode 150 includes a bonding pad 152 and a finger portion 154 extended from the bonding pad 152, the bonding pad 152 is located above the main body 132, the finger portion 154 is located above the extension portion 134, and the extension portion 234 has a plurality of widths along the extending direction of the finger portion 154.

Since the extension portion 234 has a plurality of widths along the extending direction of the finger portion 154, the extension portion 234 can be divided into a plurality of portions having different widths. Specifically, the portion in the extension portion 234 having a greater width has greater blocking power against the driving current from the second electrode 150, and the portion in the extension portion 234 having a smaller width has smaller blocking power against the driving current from the second electrode 150. In the present embodiment, the locations of the current-collecting regions in the light-emitting diode chip 200 can be controlled via the extension portion 234 having a plurality of widths to improve the luminous efficiency of the light-emitting diode chip 200.

In the present embodiment, the light-emitting layer 114 is disposed on the first-type doped semiconductor layer 112 to expose a portion of the first-type doped semiconductor layer 112, and the first electrode 120 is disposed on the portion of the first-type doped semiconductor layer 112 exposed by the light-emitting layer 114. In other words, the light-emitting diode chip 200 of the present embodiment is a horizontal-type light-emitting diode chip. For instance, the first-type doped semiconductor layer 112 in the semiconductor device layer 110 is, for instance, an N-type doped semiconductor layer, the second-type doped semiconductor layer 116 is, for instance, a P-type doped semiconductor layer, and the light-emitting layer 114 is, for instance, a multiple quantum well (MQW) formed by a plurality of alternately-stacked well layers and barrier layers. Moreover, the semiconductor device layer 110 of the present embodiment is, for instance, manufactured on a substrate SUB via an epitaxial process, and the substrate SUB can be, for instance, a sapphire substrate, a silicon substrate, or a silicon carbide substrate.

It should be mentioned that, the above semiconductor device layer 110 can further include a buffer layer 160, and the buffer layer 160 is generally formed on the substrate SUB before the manufacture of the first-type doped semiconductor layer 112. In other words, the buffer layer 160 can be optionally fonned between the substrate SUB and the semiconductor device layer 110 to provide suitable stress relief and improve the epitaxial quality of a subsequently-formed thin film.

In the present embodiment, the first electrode 120 is, for instance, a metal material having good Ohmic contact with the first-type doped semiconductor layer 112, the material of the current-blocking layer 230 is, for instance, a dielectric layer, the material of the current-spreading layer 140 is, for instance, a transparent conducting material, and the second electrode 150 is, for instance, a metal material having good Ohmic contact with the current-spreading layer 140. For instance, the material of the first electrode 120 includes a conducting material such as chromium (Cr), gold (Au), aluminum (Al), or titanium (Ti), the material of the current-blocking layer 230 includes a dielectric material such as silicon oxide (SiOx) or silicon nitride (SiNx), the material of the current-spreading layer 140 includes a transparent conducting material such as indium-tin-oxide (ITO) or indium-zinc-oxide (IZO), and the material of the second electrode 150 includes a conducting material such as Cr, Au, Al, or Ti.

The current-blocking layer 230 of the present embodiment can adopt different designs, and in the following, different designs of the current-blocking layer 230 are described with reference to FIG. 3A to FIG. 3C.

As shown in FIG. 3A and FIG. 3B, the widths of the extension portion 234 of the present embodiment can vary periodically along the extending direction of the finger portion 154. More specifically, the extension portion 234 has two or more widths, and the width of the extension portion 234 at any location is greater than the width of the finger portion 154 (as shown in FIG. 3A), or the width of the extension on portion 234 at a partial region is equal to the width of the finger portion 154, and the widths at other regions are greater than the width of the finger portion 154 (as shown in FIG. 3B). For instance, the extension portion 234 of the present embodiment includes a plurality of current-blocking patterns 234a and a plurality of connecting patterns 234b arranged along the extending direction of the finger portion 154, wherein the current-blocking patterns 234a are connected to one another via the connecting patterns 234b. Moreover, the connecting patterns 234b overlap the finger portion 154, and the width of each of the connecting patterns 234b along the extending direction of the finger portion 154 is greater than the width of the finger portion 154 (as shown FIG. 3A), or the width of each of the connecting patterns 234b is equal to the width of the finger portion 154 (as shown in FIG. 3B). As shown in FIG. 3C, in the current-blocking layer 230 of the present embodiment, the widths of the extension portion 234 are gradually changed along the extending direction of the finger portion 154, and the widths of the extension portion 234 are greater closer to the first electrode 120.

### Third Embodiment

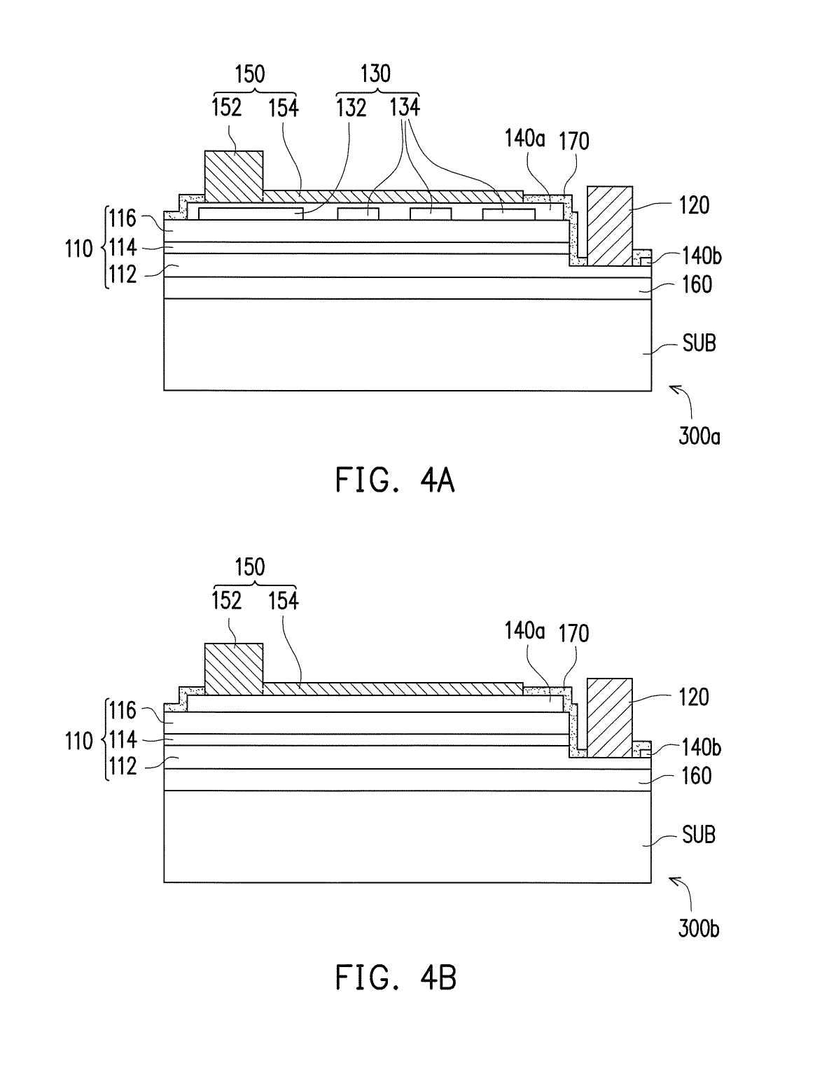

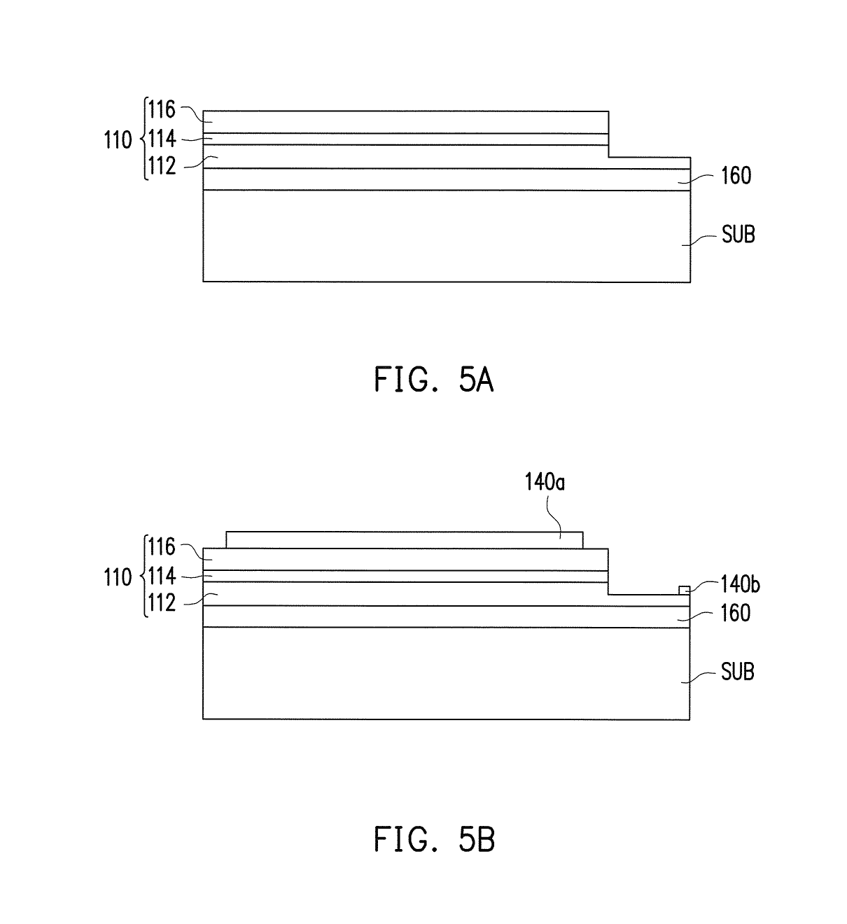

FIG. 4A to FIG. 4B are cross-sectional views of different light-emitting diode chips according to the third embodiment of the invention. Please refer to FIG. 4A first. In the present embodiment, a light-emitting diode chip 300a is similar to the light-emitting diode chip 100a of the embodiment of FIG. 1A. The components of the light-emitting diode chip 300a and relating description are as provided for the light-emitting diode chip 100a of the embodiment of FIG. 1A and are not repeated herein. The difference between the light-emitting diode chip 300a and the light-emitting diode chip 100a is that the light-emitting diode chip 300a includes a current-spreading layer 140a and a current-spreading layer 140b. The current-spreading layer 140a is disposed on the second-type doped semiconductor layer 116 to cover the current-blocking layer 130, and the current-spreading layer 140b is disposed on the first-type doped semiconductor layer 112. In the present embodiment, the light-emitting diode chip 300a further includes a protective layer 170 disposed on the semiconductor device layer 110. The current-spreading layer 140a and the current-spreading layer 140b are disposed between the protective layer 170 and the semiconductor device layer 110. Specifically, the protective layer 170 is disposed on the current-spreading layer 140a and the current-spreading layer 140b, and the material of the protective layer 170 can also be a light-permeable film layer such as silicon oxide. The index of refraction of the protective layer 170 material is, for instance, between 1.4 and 1.6.

In the present embodiment, the materials of the current-spreading layer 140a and the current-spreading layer 140b include a transparent conducting material. Moreover, the index of refraction of the current-spreading layer 140a is between the indexes of refraction of the protective layer 170 and the second-type doped semiconductor layer 116, and the index of refraction of the current-spreading layer 140b is between the indexes of refraction of the protective layer 170 and the first-type doped semiconductor layer 112. For instance, the index of refraction of the current-spreading layer 140b (or the current-spreading layer 140a) is, for instance, 1.9, the index of refraction of the protective layer 170 is, for instance, between 1.4 and 1.6, and the index of refraction of the first-type doped semiconductor layer 112 (or the second-type doped semiconductor layer 116) is, for instance, 2.3. Specifically, since in the present embodiment, the index of refraction of the stacked first-type doped semiconductor layer 112, current-spreading layer 140b, and protective layer 170 is gradually changed, the current-spreading layer 140b eliminates the difference in index of refraction between the protective layer 170 and the first-type doped semiconductor layer 112. When light passes through the first-type doped semiconductor layer 112, the current-spreading layer 140b, and the protective layer 170 in order, since the difference in index of refraction between the stacked structure is less, the light emitted by the light-emitting layer 114 has a greater total reflection angle, such that total reflection occurs less readily thereto and the refraction ratio is increased as a result. Therefore, the optical efficiency of the light-emitting diode chip 300a is increased. In the present embodiment, the materials of the current-spreading layer 140a and the current-spreading layer 140b are ITO. However, in some embodiments, the materials of the current-spreading layer 140a and the current-spreading layer 140b can also be ITO, nickel (Ni), Au, Cr, Ti, Al, or a combination thereof, and the invention is not limited thereto.

In the present embodiment, similar to the light-emitting diode chip 100a of the embodiment of FIG. 1A, the locations of the current-collecting regions in the light-emitting diode chip 300a can be controlled via the pattern designs of the extension portion 134 and the finger portion 154 and the overlapping condition of the two, so as to improve the luminous efficiency of the light-emitting diode chip 300a.

Next, please refer to FIG. 4B. In the present embodiment, a light-emitting diode chip 300b is similar to the light-emitting diode chip 300a of the embodiment of FIG. 4A. The components of the light-emitting diode chip 300b and relating description are as provided for the light-emitting diode chip 300a of the embodiment of FIG. 4A and are not repeated herein. The difference between the light-emitting diode chip 300b and the light-emitting diode chip 300a is that the light-emitting diode chip 300b does not include a current-blocking layer. Moreover, in the present embodiment, the index of refraction of the current-spreading layer 140a is between the indexes of refraction of the protective layer 170 and the second-type doped semiconductor layer 116, and the index of refraction of the current-spreading layer 140b is between the indexes of refraction of the protective layer 170 and the first-type doped semiconductor layer 112. Therefore, similar to the light-emitting diode chip 300a of the embodiment of FIG. 4A, total reflection occurs less readily to the light emitted by the light-emitting layer 114 of the light-emitting diode chip 300b, such that the optical efficiency of the light-emitting diode chip 300b is increased.

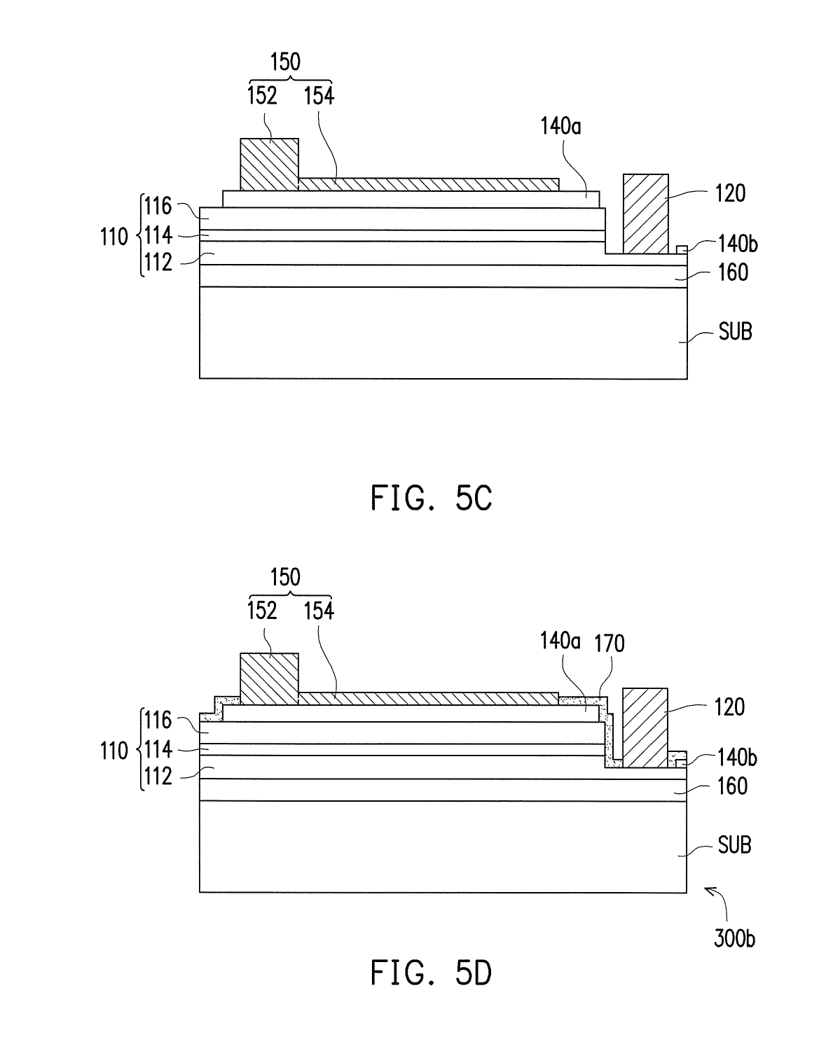

FIG. 5A to FIG. 5D are flowcharts of the manufacturing method of the light-emitting diode chip of the embodiment of FIG. 4B. Please refer to FIG. 5A first. In the present embodiment, the manufacturing method of the light-emitting diode chip 300a of the embodiment of FIG. 4A includes growing the semiconductor device layer 110 on the substrate SUB. The semiconductor device layer 110 has the first-type doped semiconductor layer 112, the light-emitting layer 114, and the second-type doped semiconductor layer 116. Specifically, the first-type doped semiconductor layer 112 is formed on the substrate SUB, the light-emitting layer 114 is formed on the first-type doped semiconductor layer 112, and the second-type doped semiconductor layer 116 is formed on the light-emitting layer 114. Moreover, in the present embodiment, before the manufacture of the first-type doped semiconductor layer 112, the buffer layer 160 is first formed on the substrate SUB.

Next, please refer to FIG. 5A and FIG. 5B. In the present embodiment, the light-emitting layer 114 is disposed on the first-type doped semiconductor layer 112 to expose a portion of the first-type doped semiconductor layer 112. Specifically, the first-type doped semiconductor layer 112, the light-emitting layer 114, and the second-type doped semiconductor layer 116 are, for instance, formed by epitaxy. Moreover, a portion of the first-type doped semiconductor layer 112, the light-emitting layer 114, and the second-type doped semiconductor layer 116 are removed via etching to expose a portion of the first-type doped semiconductor layer 112. In the present embodiment, the manufacturing method of the light-emitting diode chip 300a includes forming a current-spreading layer 140a on the second-type doped semiconductor layer 116 and on a portion of the first-type doped semiconductor layer 112 exposed by the current-spreading layer 140b on the light-emitting layer 114. Specifically, the current-spreading layer 140a and the current-spreading layer 140b can further expose the first-type doped semiconductor layer 112 and the second-type doped semiconductor layer 116 by etching and keeping a partial region so as to provide space for disposing a subsequent electrode and to prevent a short circuit caused by the connection between the current-spreading layer 140a and the current-spreading layer 140b at the same time.

Referring to FIG. 5C, in the present embodiment, the manufacturing method of the light-emitting diode chip 300a includes forming the first electrode 120 and the second electrode 150 such that the first electrode 120 and the second electrode 150 are respectively electrically connected to the first-type doped semiconductor layer 112 and the current-spreading layer 140a. Specifically, the first electrode 120 is disposed on the portion of the first-type doped semiconductor layer 112 exposed by the light-emitting layer 114.

Then, referring to FIG. 5D, in the present embodiment, the manufacturing method of the light-emitting diode chip 300a includes forming the protective layer 170 on the surface of the semiconductor device layer 110 and covering a portion of the current-spreading layer 140a and a portion of the current-spreading layer 140b. Specifically, the index of refraction of the current-spreading layer 140a is between the indexes of refraction of the protective layer 170 and the second-type doped semiconductor layer 116, and the index of refraction of the current-spreading layer 140b is between the indexes of refraction of the protective layer 170 and the first-type doped semiconductor layer 112.

### Fourth Embodiment

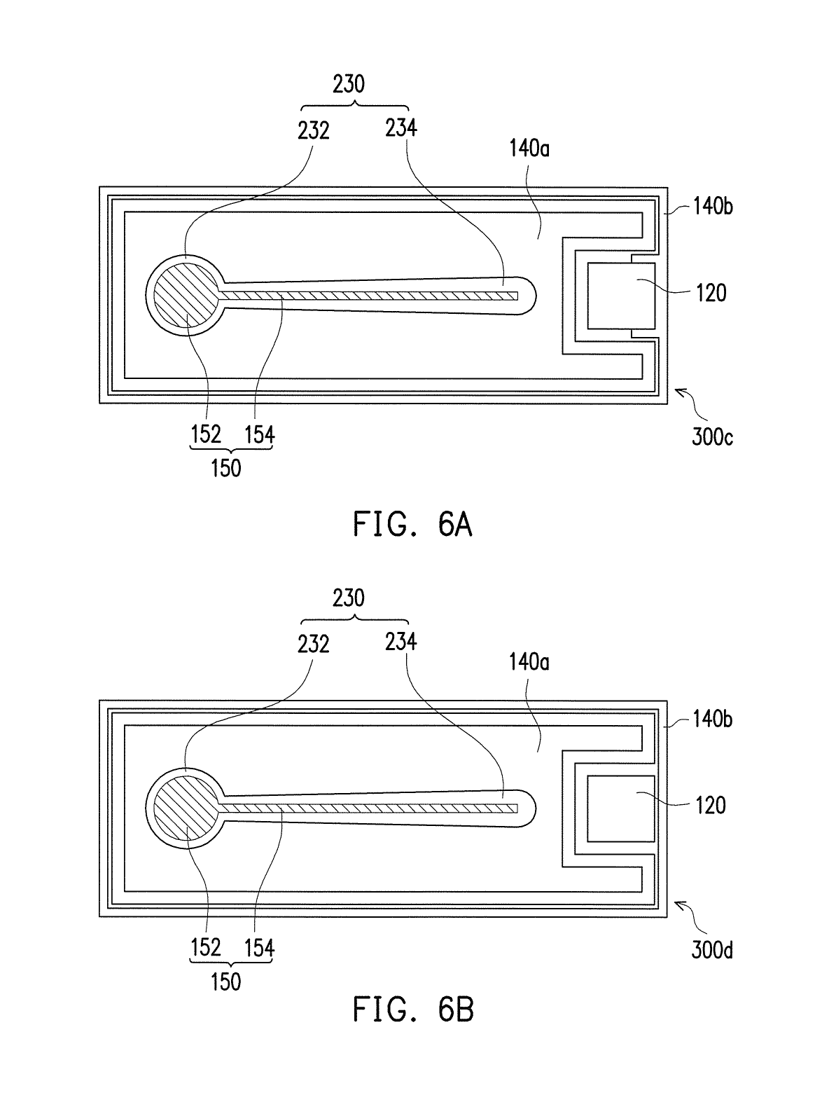

FIG. 6A to FIG. 6B are top views of different light-emitting diode chips according to the fourth embodiment of the invention. Please refer to FIG. 6A and FIG. 6B. In the present embodiment, a light-emitting diode chip 300c of FIG. 6A and a light-emitting diode chip 300d of FIG. 6B are similar to the light-emitting diode chip 200 of the embodiment of FIG. 3C. The components of the light-emitting diode chip 300c and relating description and the components of the light-emitting diode chip 300d and relating description are as provided for the light-emitting diode chip 200 of the embodiment of FIG. 3C and are not repeated herein. In the present embodiment, the difference between the light-emitting diode chip 300c of FIG. 6A and the light-emitting diode chip 300d of FIG. 6B is that the current-spreading layer 140b of the light-emitting diode chip 300c is in contact with a side of the first electrode 120, and the current-spreading layer 140b of the light-emitting diode chip 300d is not in contact with the side of the first electrode 120. Specifically, the current-spreading layer 140b can be controlled to be in contact or not be in contact with the side of the first electrode 120 by changing the technical means of the photomask in the process, and the invention is not limited thereto. Moreover, the current-spreading layer 140a and the current-spreading layer 140b of an embodiment of the invention have a low effect on electrical property. Therefore, the current-spreading layer 140a and the current-spreading layer 140b can reduce variation in the index of refraction on the light-exit path of the light without affecting the electrical performance of the light-emitting diode chip to improve the optical efficiency of the light-emitting diode chip.

### Fifth Embodiment

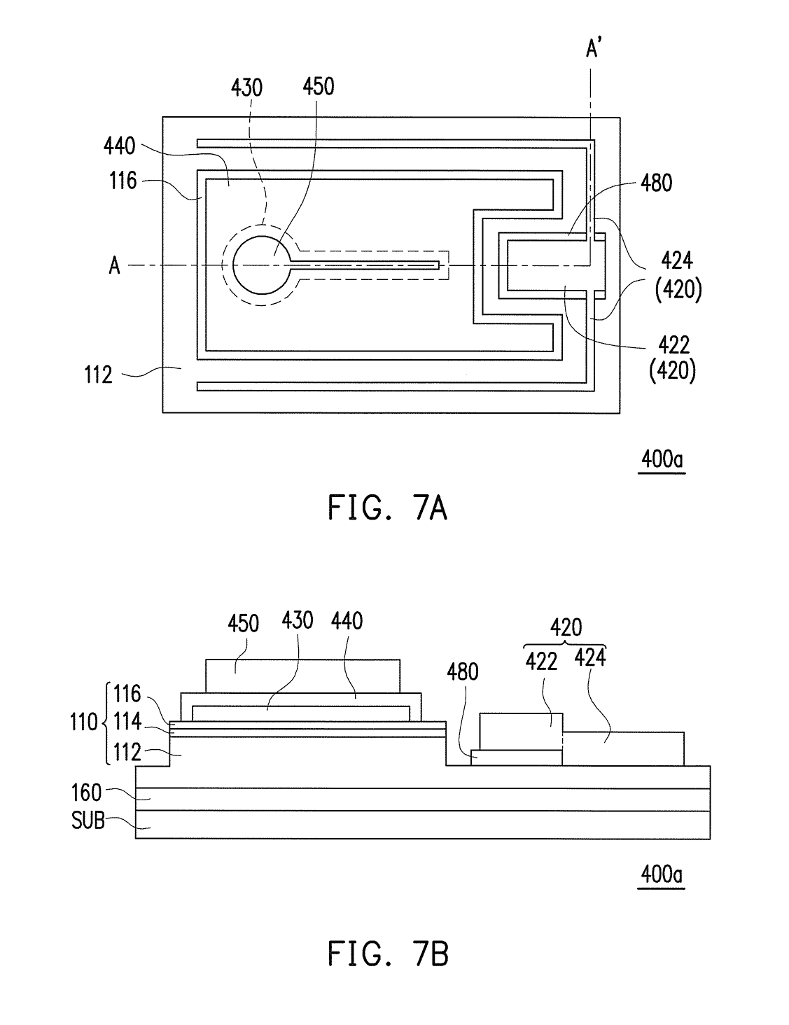

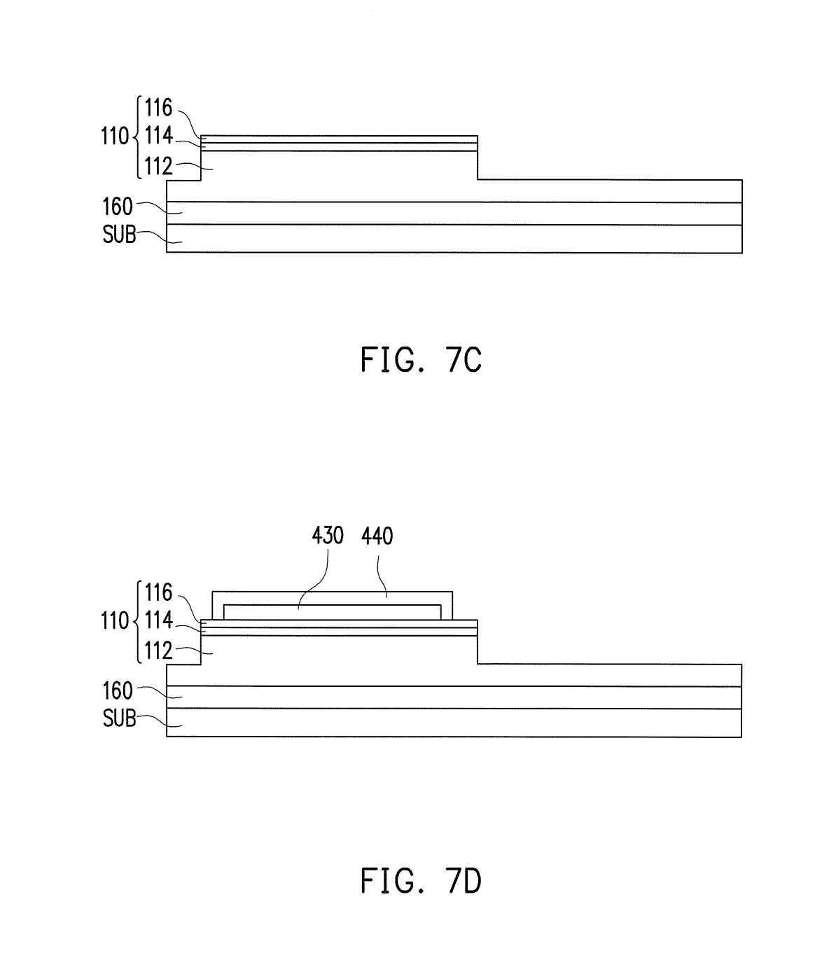

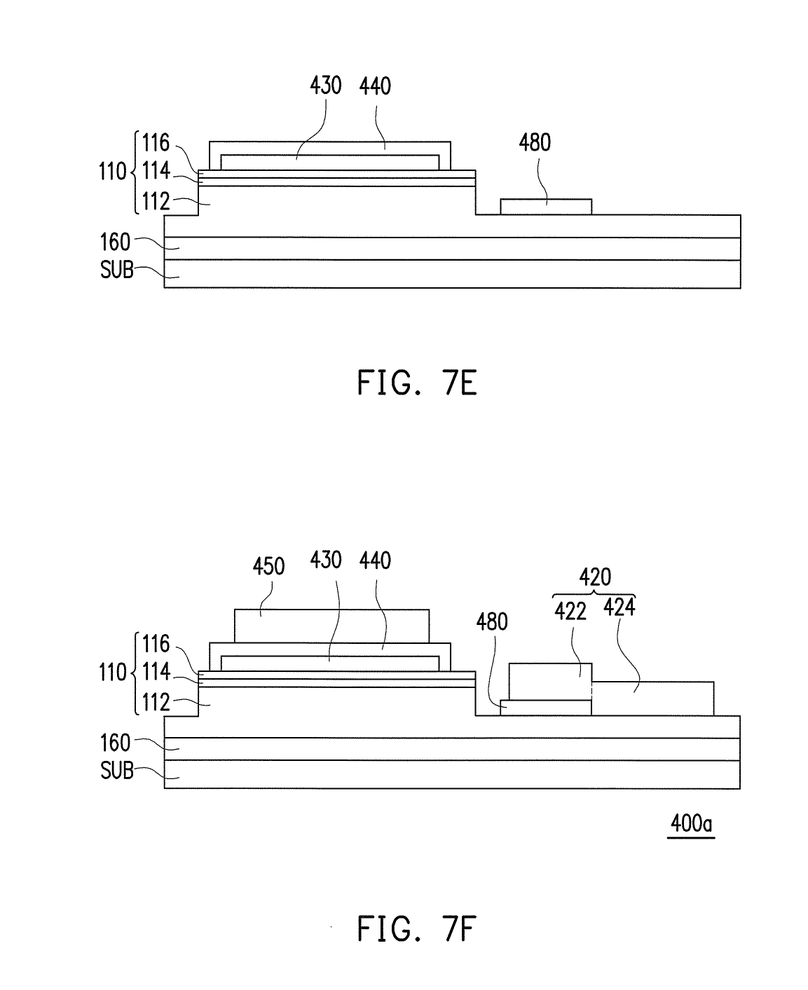

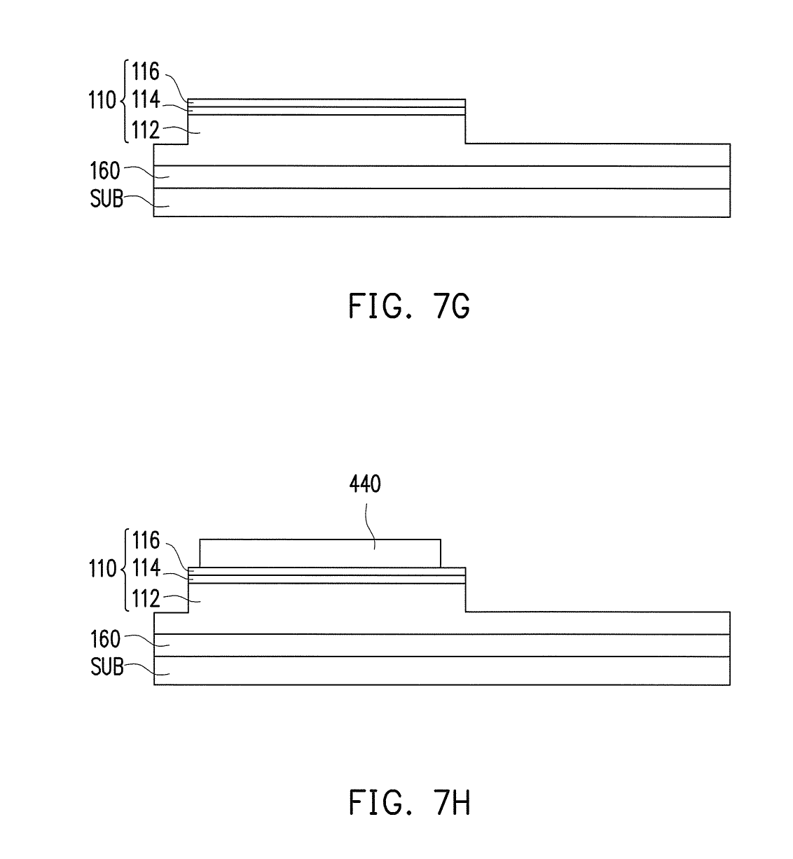

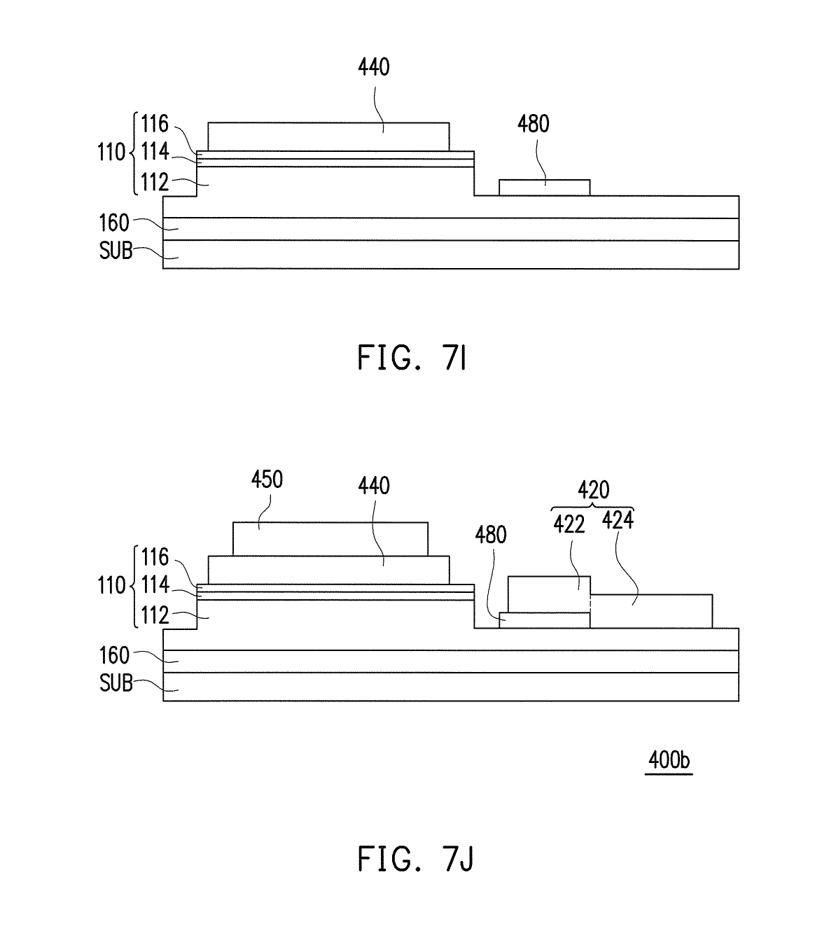

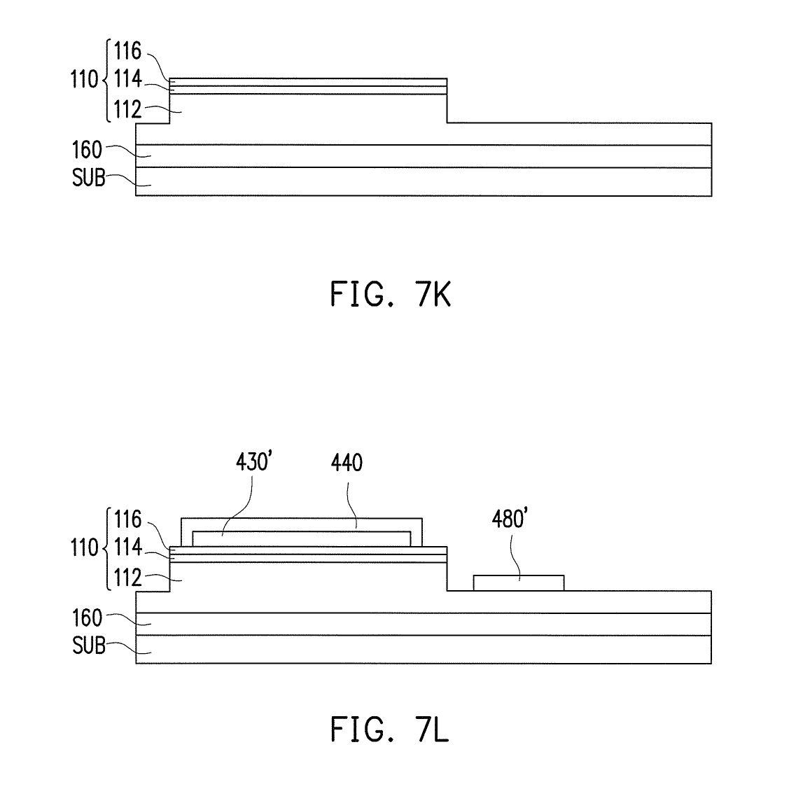

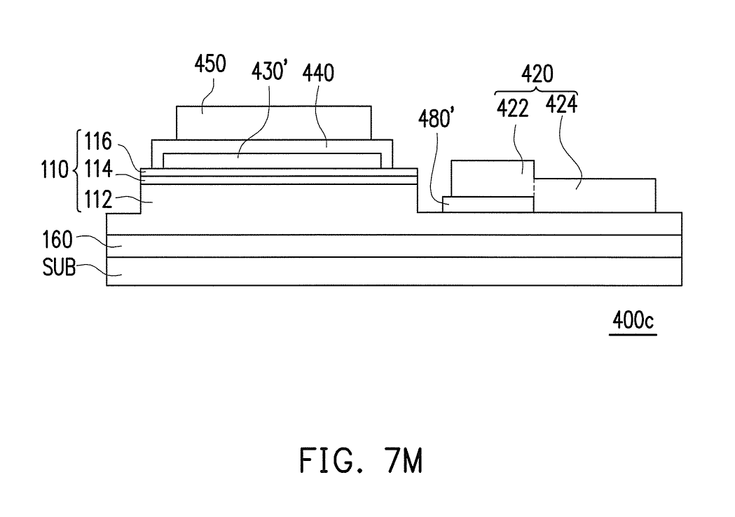

FIG. 7A is a top view of the light-emitting diode chip according to the fifth embodiment of the invention, and FIG. 7B is a cross-sectional view of the light-emitting diode chip of FIG. 7A along line A-A′. In the present embodiment, a light-emitting diode chip 400a is similar to the light-emitting diode chip 100a of FIG. 1A. Specifically, the light-emitting diode chip 400a includes a semiconductor device layer 110, a current-spreading layer 440, a first electrode 420, an insulating layer 480, and a second electrode 450. The semiconductor device layer 110 includes the first-type doped semiconductor layer 112, the light-emitting layer 114, and the second-type doped semiconductor layer 116. The light-emitting layer 114 is located between the first-type doped semiconductor layer 112 and the second-type doped semiconductor layer 116. In the present embodiment, the current-spreading layer 440 is disposed on the second-type doped semiconductor layer 116. The first electrode 420 is electrically connected to the first-type doped semiconductor layer 112, and the insulating layer 480 is disposed between the first electrode 420 and the first-type doped semiconductor layer 112. Moreover, the second electrode 450 is electrically connected to the second-type doped semiconductor layer 116 via the current-spreading layer 440. Specifically, the light-emitting diode chip 400a further includes a current-blocking layer 430 disposed between the current-spreading layer 440 and the second-type doped semiconductor layer 116. The current-blocking layer 430 can be, for instance, the current-blocking layer 130 of the light-emitting diode chip 100a of the embodiment of FIG. 1A, and can also be other types of current-blocking layer, and the invention is not limited thereto. Moreover, the components and the disposition of the components of the light-emitting diode chip 400a and relating description are as provided for the light-emitting diode chip 100a of FIG. 1A and are not repeated herein.

In the present embodiment, the first electrode 420 includes a bonding portion 422 and branched portions 424 extended from the bonding portion 422. Specifically, the bonding portion 422 is disposed above the insulating layer 480. The insulating layer 480 is configured to block electrons from circulating to the first-type doped semiconductor layer 112 from the bonding portion 422 of the first electrode 420, such that the electrons are circulated from the bonding portion 422 of the first electrode 420 to the branched portions 424 and the electrons are circulated to the first-type doped semiconductor layer 112 via the branched portions 424. In the present embodiment, since the branched portions 424 are extended from the bonding portion 422 to a location farther than the bonding portion 422, the electrons provided by driving the light-emitting diode chip 400a externally are circulated from the bonding portion 422 to the branched portions 424, and are spread to a location farther than the bonding portion 422 via the branched portions 424, such that the electrons can reach the portion of the first-type doped semiconductor layer 112 corresponding to the location farther than the bonding portion 422. Specifically, the electrons provided by driving the light-emitting diode chip 400a externally reach the corresponding location of the first-type doped semiconductor layer 112 via the branched portions 424 distributed on the first-type doped semiconductor layer 112. Therefore, the region of the first-type doped semiconductor layer 112 receiving the electrons at least includes a region of the branched portions 424 in contact with the first-type doped semiconductor layer 112, such that the combination probability of the electrons provided by the first electrode 420 and the electron holes provided by the second electrode 450 is increased and more photons are generated as a result. Therefore, the luminous efficiency of the light-emitting diode chip 400a is increased.

In the present embodiment, the material of the insulating layer 480 is, for instance, a dielectric layer. For instance, the material of the insulating layer 480 includes a dielectric material such as SiOx or SiNx. In some embodiments, the material of the insulating layer 480 can also be other types of dielectric material, and the material of the insulating layer 480 can be the same or different than the material of the current-blocking layer 430, and the invention is not limited thereto. Moreover, in the present embodiment, the light-emitting diode chip 400a can include the protective layer 170 of the light-emitting diode chip 300a of the embodiment of FIG. 4A and FIG. 4B, and the invention is also not limited thereto.

### Sixth Embodiment

FIG. 7C to FIG. 7F, FIG. 7G to FIG. 7J, and FIG. 7K to FIG. 7M are flowcharts of the manufacturing method of different light-emitting diode chips according to the sixth embodiment of the invention. Please refer first to FIG. 7C to FIG. 7F, and refer to FIG. 5A to FIG. 5D at the same time. In the present embodiment, the structure of the light-emitting diode chip 400a is the same as the light-emitting diode chip 400a of the embodiment of FIG. 7A and FIG. 7B. The manufacturing method of the light-emitting diode chip 400a of the present embodiment is similar to the manufacturing method of the light-emitting diode chip 300a of the embodiment of FIG. 5A to FIG. 5D. Specifically, referring first to FIG. 7C, the manufacturing method of the light-emitting diode chip 400a of the present embodiment includes growing the semiconductor device layer 110 on the substrate SUB. The semiconductor device layer 110 has the first-type doped semiconductor layer 112, the light-emitting layer 114, and the second-type doped semiconductor layer 116. The first-type doped semiconductor layer 112 is formed on the substrate SUB, the light-emitting layer 114 is formed on the first-type doped semiconductor layer 112, and the second-type doped semiconductor layer 116 is formed on the light-emitting layer 114. Moreover, in the present embodiment, before the manufacture of the first-type doped semiconductor layer 112, the buffer layer 160 is first formed on the substrate SUB. Moreover, the light-emitting layer 114 is disposed on the first-type doped semiconductor layer 112 to expose a portion of the first-type doped semiconductor layer 112. Then, referring to FIG. 7D, the current-blocking layer 430 and the current-spreading layer 440 are formed on the second-type doped semiconductor layer 116, and the current-blocking layer 430 is located between the current-spreading layer 440 and the second-type doped semiconductor layer 116.

Then, please refer to FIG. 7E. In the present embodiment, the manufacturing method of the light-emitting diode chip 400a includes forming the insulating layer 480 on the portion of the first-type doped semiconductor layer 112 exposed by the light emitting layer 114. Then, referring to FIG. 7F, the first electrode 420 and the second electrode 450 are formed such that the first electrode 420 and the second electrode 450 are respectively electrically connected to the first-type doped semiconductor layer 112 and the current-spreading layer 440 to form the light-emitting diode chip 400a. Specifically, the first electrode 420 of the light-emitting diode chip 400a includes the bonding portion 422 and the branched portions 424 extended from the bonding portion 422, and the bonding portion 422 is disposed above the insulating layer 480.

FIG. 7G to FIG. 7J are flowcharts of the manufacturing method of the other light-emitting diode chips of the sixth embodiment of the invention. Please refer to FIG. 7G to FIG. 7J, and at the same time refer to FIG. 7C to FIG. 7F. A light-emitting diode chip 400b is similar to the light-emitting diode chip 400a of FIG. 7C to FIG. 7F, and the manufacturing method of the light-emitting diode chip 400b of the present embodiment is similar to the manufacturing method of the light-emitting diode chip 400a of the embodiment of FIG. 7C to FIG. 7F. In the present embodiment, referring first to FIG. 7G, the manufacturing method of the light-emitting diode chip 400b of the present embodiment includes growing the semiconductor device layer 110 on the substrate SUB. Moreover, referring to FIG. 7H, the current-spreading layer 440 is formed on the second-type doped semiconductor layer 116. Specifically, in the manufacturing method of the light-emitting diode chip 400b, a current-blocking layer is not formed on the second-type doped semiconductor layer 116. Then, referring to FIG. 7I, the insulating layer 480 is formed on the portion of the first-type doped semiconductor layer 112 exposed by the light-emitting layer 114. Then, referring to FIG. 7J, the first electrode 420 and the second electrode 450 are formed such that the first electrode 420 and the second electrode 450 are respectively electrically connected to the first-type doped semiconductor layer 112 and the current-spreading layer 440 to form the light-emitting diode chip 400b.

FIG. 7K to FIG. 7M are flowcharts of the manufacturing method of the other light-emitting diode chips of the sixth embodiment of the invention. Please refer to FIG. 7K to FIG. 7M, and at the same time refer to FIG. 7C to FIG. 7F. A light-emitting diode chip 400c is similar to the light-emitting diode chip 400a of FIG. 7C to FIG. 7F, and the manufacturing method of the light-emitting diode chip 400c of the present embodiment is similar to the manufacturing method of the light-emitting diode chip 400a of the embodiment of FIG. 7C to FIG. 7F. In the present embodiment, referring first to FIG. 7K, the manufacturing method of the light-emitting diode chip 400c of the present embodiment includes growing the semiconductor device layer 110 on the substrate SUB. Moreover, referring to FIG. 7L, a current-blocking layer 430′ is formed on the second-type doped semiconductor layer 116, and an insulating layer 480′ is formed on the portion of the first-type doped semiconductor layer 112 exposed by the light-emitting layer 114 at the same time. Specifically, the materials of the current-blocking layer 430′ and the insulating layer 480′ can be the same or different. Moreover, the current-spreading layer 440 is formed on the second-type doped semiconductor layer 116 such that the current-blocking layer 430′ is located between the current-spreading layer 440 and the second-type doped semiconductor layer 116. Then, referring to FIG. 7M, the first electrode 420 and the second electrode 450 are formed such that the first electrode 420 and the second electrode 450 are respectively electrically connected to the first-type doped semiconductor layer 112 and the current-spreading layer 440 to form the light-emitting diode chip 400c.

### Seventh Embodiment

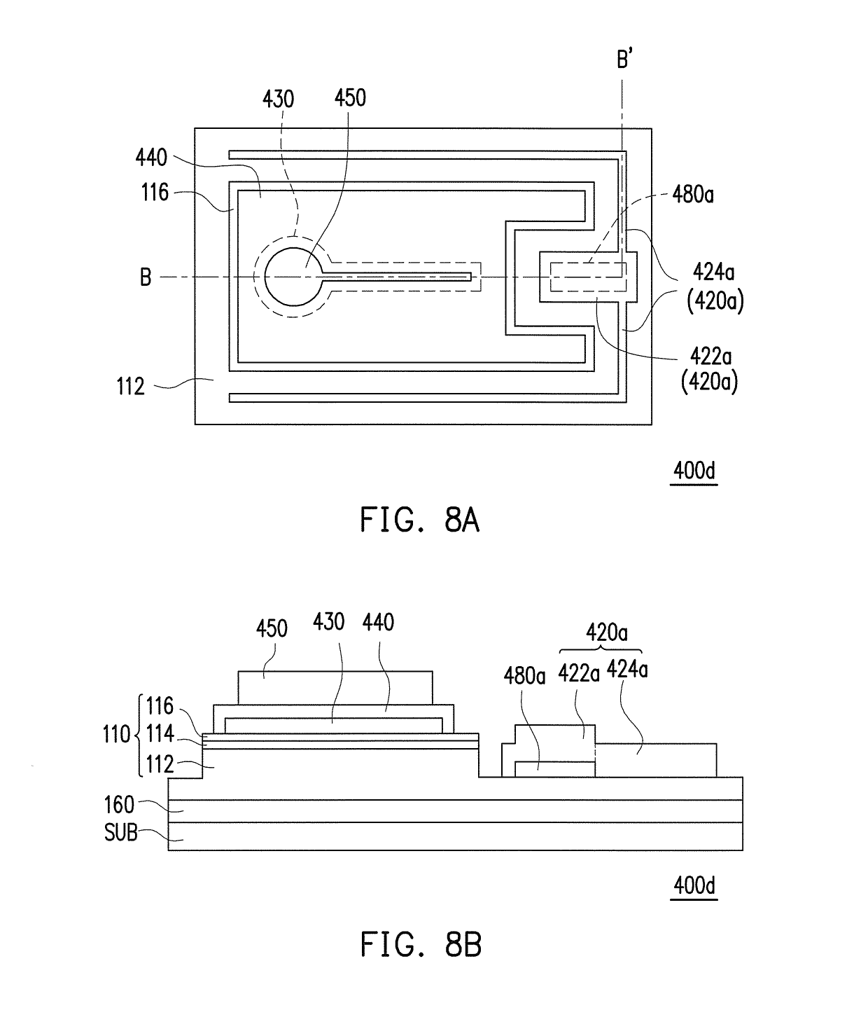

FIG. 8A is a top view of the light-emitting diode chip according to the seventh embodiment of the invention, and FIG. 8B is a cross-sectional view of the light-emitting diode chip of FIG. 8A along line B-B′. Please refer to FIG. 8A and FIG. 8B. In the present embodiment, a light-emitting diode chip 400d is the same as the light-emitting diode chip 400a of the embodiment of FIG. 7A and FIG. 7B. The components of the light-emitting diode chip 400d and relating description are as provided for the light-emitting diode chip 400a of FIG. 7A and FIG. 7B and are not repeated herein. The difference between the light-emitting diode chip 400d and the light-emitting diode chip 400a is that, a first electrode 420a of the light-emitting diode chip 400d includes a bonding portion 422a and branched portions 424a extended from the bonding portion 422a. Specifically, the bonding portion 422a is disposed above an insulating layer 480a, and the bonding portion 422a covers the insulating layer 480a. In the present embodiment, the insulating layer 480a is disposed between the first electrode 420a and the first-type doped semiconductor layer 112, and the first electrode 420a includes the branched portions 424a extended from the bonding portion 422a. Therefore, in the light-emitting diode chip 400d, the combination probability of the electrons provided by the first electrode 420a and the electron holes provided by the second electrode 450 is increased to generate more photons, such that the light-emitting diode chip 400d has a similar effect of increasing luminous efficiency to the light-emitting diode chip 400a of the embodiment of FIG. 7A and FIG. 7B.

### Eighth Embodiment

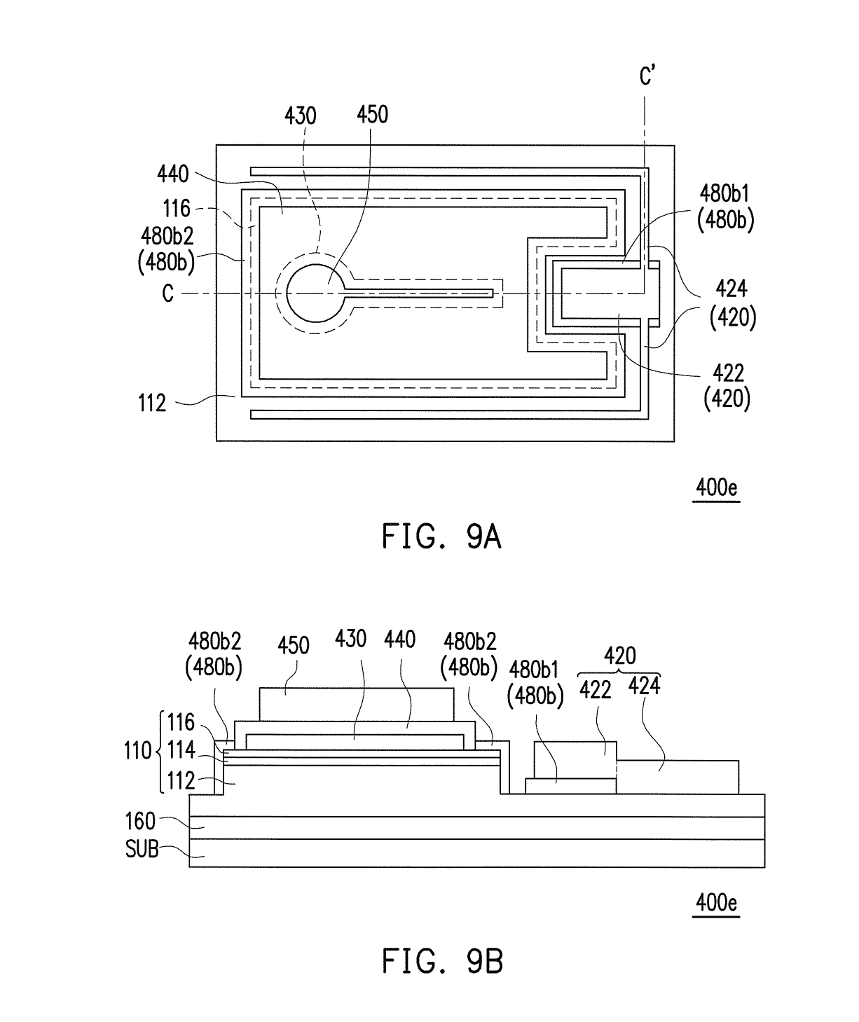

FIG. 9A is a top view of the light-emitting diode chip according to the eighth embodiment of the invention, and FIG. 9B is a cross-sectional view of the light-emitting diode chip of FIG. 9A along line C-C′. Please refer to FIG. 9A and FIG. 9B. In the present embodiment, a light-emitting diode chip 400e is similar to the light-emitting diode chip 400a of the embodiment of FIG. 7A and FIG. 7B. The components of the light-emitting diode chip 400e and relating description are as provided for the light-emitting diode chip 400a of FIG. 7A and FIG. 7B and are not repeated herein. The difference between the light-emitting diode chip 400e and the light-emitting diode chip 400a is that, an insulating layer 480b of the light-emitting diode chip 400e includes an insulating layer 480b1 and an insulating layer 480b2. In the present embodiment, the insulating layer 480b1 is disposed between the first electrode 420 and the first-type doped semiconductor layer 112, and the insulating layer 480b2 is disposed on the second-type doped semiconductor layer 116. Specifically, the insulating layer 480b2 covers the second-type doped semiconductor layer 116, the light-emitting layer 114, and the exposed portion of first-type doped semiconductor layer 112. Moreover, in the present embodiment, the insulating layer 480b 1 (insulating layer 480b), the insulating layer 480b2 (insulating layer 480b), and the current-blocking layer 430 can adopt the same or different material, and the invention is not limited thereto. In the present embodiment, the insulating layer 480b1 is disposed between the first electrode 420 and the first-type doped semiconductor layer 112, and the first electrode 420 includes the branched portions 424 extended from the bonding portion 422. Therefore, the light-emitting diode chip 400e has a similar effect of increasing luminous efficiency to the light-emitting diode chip 400a of the embodiment of FIG. 7A and FIG. 7B.

### Ninth Embodiment

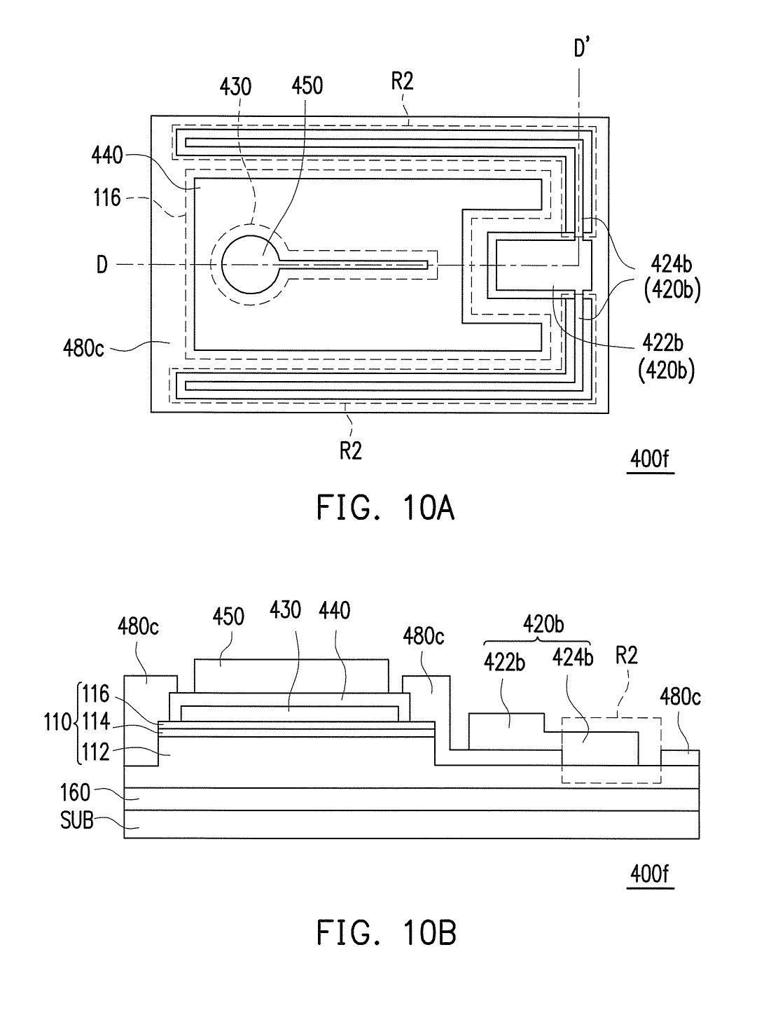

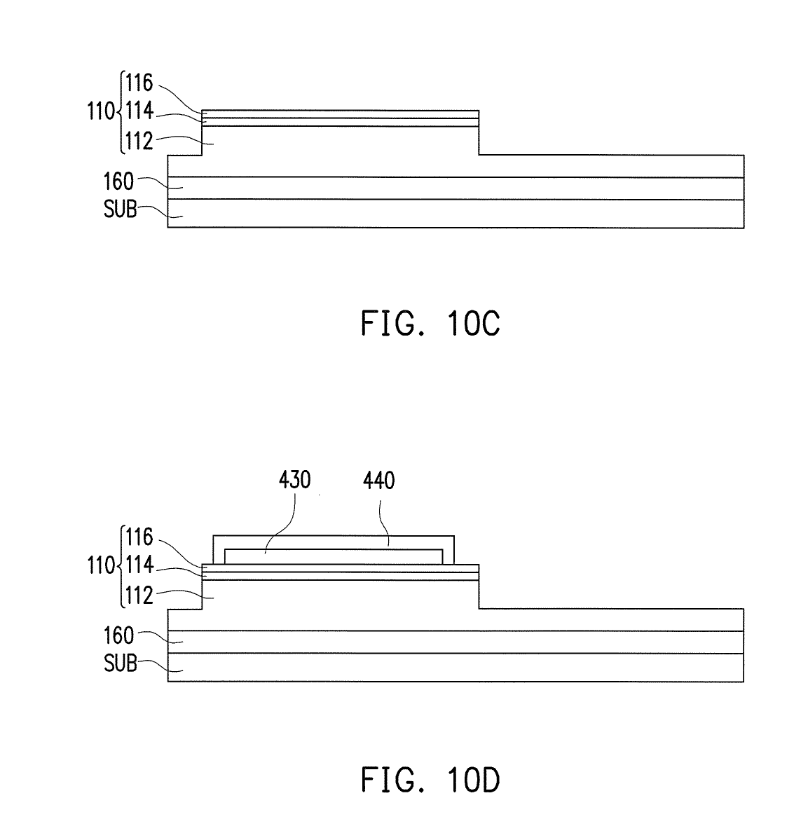

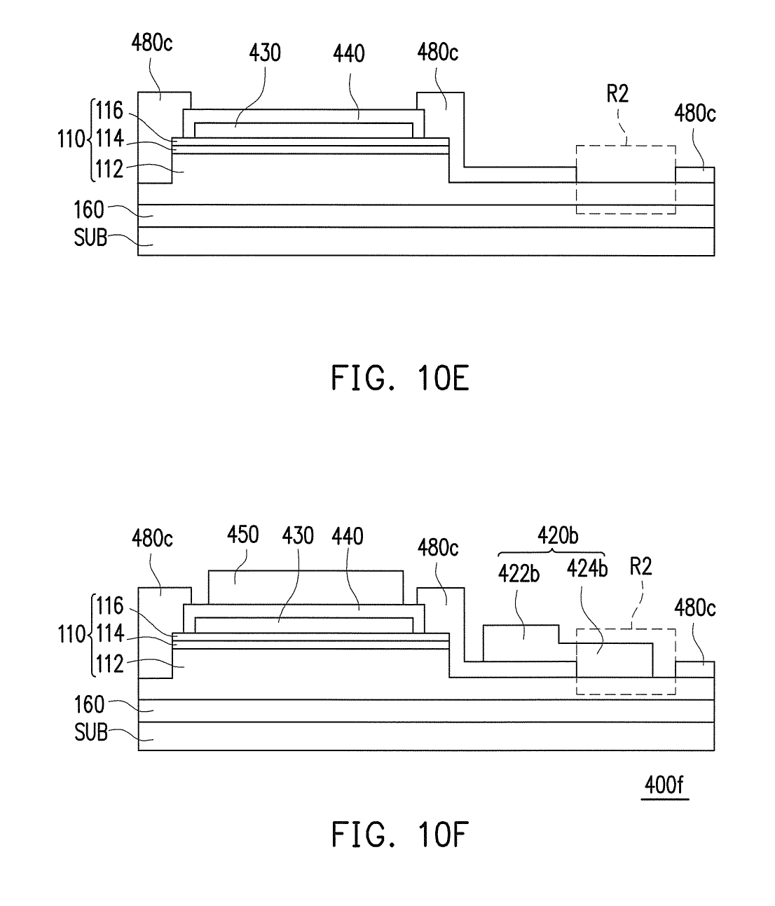

FIG. 10A is a top view of the light-emitting diode chip according to the ninth embodiment of the invention, and FIG. 10B is a cross-sectional view of the light-emitting diode chip of FIG. 10A along line D-D′. Please refer to FIG. 10A and FIG. 10B. In the present embodiment, a light-emitting diode chip 400f is similar to the light-emitting diode chip 400a of the embodiment of FIG. 7A and FIG. 7B. The components of the light-emitting diode chip 400f and relating description are as provided for the light-emitting diode chip 400a of FIG. 7A and FIG. 7B and are not repeated herein. The difference between the light-emitting diode chip 400f and the light-emitting diode chip 400a is that, an insulating layer 480c of the light-emitting diode chip 400f is disposed on the first-type doped semiconductor layer 112. The portion of the first-type doped semiconductor layer 112 without the insulating layer 480c forms a region R2. In the present embodiment, a first electrode 420b of the light-emitting diode chip 400f includes a bonding portion 422b and branched portions 424b extended from the bonding portion 422b, and the branched portions 424b are disposed in the region R2. Specifically, in some embodiments, the branched portions 424b disposed in the region R2 and the insulating layer 480c have a suitable gap. Moreover, the insulating layer 480c covers the second-type doped semiconductor layer 116, the light-emitting layer 114, and a portion of the first-type doped semiconductor layer 112. Therefore, the light-emitting diode chip 400f is not readily short-circuited, and better protection is obtained. In the present embodiment, the insulating layer 480c is disposed between the first electrode 420b and the first-type doped semiconductor layer 112, and the first electrode 420b includes the branched portions 424b extended from the bonding portion 422b. Therefore, the light-emitting diode chip 400e has a similar effect of increasing luminous efficiency to the light-emitting diode chip 400a of the embodiment of FIG. 7A and FIG. 7B.

FIG. 10C to FIG. 10F are flowcharts of the manufacturing method of the light-emitting diode chip of the embodiment of FIG. 10A. Please refer to FIG. 10C to FIG. 10F. The manufacturing method of the light-emitting diode chip 400f is similar to the manufacturing method of the light-emitting diode chip 400a of FIG. 7C to FIG. 7F. Referring first to FIG. 10C, the manufacturing method of the light-emitting diode chip 400f of the present embodiment includes growing the semiconductor device layer 110 on the substrate SUB. Moreover, referring to FIG. 10D, the current-blocking layer 430 and the current-spreading layer 440 are formed on the second-type doped semiconductor layer 116, and the current-blocking layer 430 is located between the current-spreading layer 440 and the second-type doped semiconductor layer 116. Moreover, referring to FIG. 10E, the insulating layer 480c is formed on the first-type doped semiconductor layer 112. The portion of the first-type doped semiconductor layer 112 without the insulating layer 480c forms the region R2. Specifically, the insulating layer 480c covers the second-type doped semiconductor layer 116, the light-emitting layer 114, and a portion of the first-type doped semiconductor layer 112. Then, referring to FIG. 10F, the first electrode 420 and the second electrode 450 are formed such that the first electrode 420b and the second electrode 450 are respectively electrically connected to the first-type doped semiconductor layer 112 and the current-spreading layer 440 to form the light-emitting diode chip 400f. Specifically, the first electrode 420b of the light-emitting diode chip 400f includes the bonding portion 422b and the branched portions 424b extended from the bonding portion 422b, and the branched portions 424b are disposed in the region R2.

### Tenth Embodiment

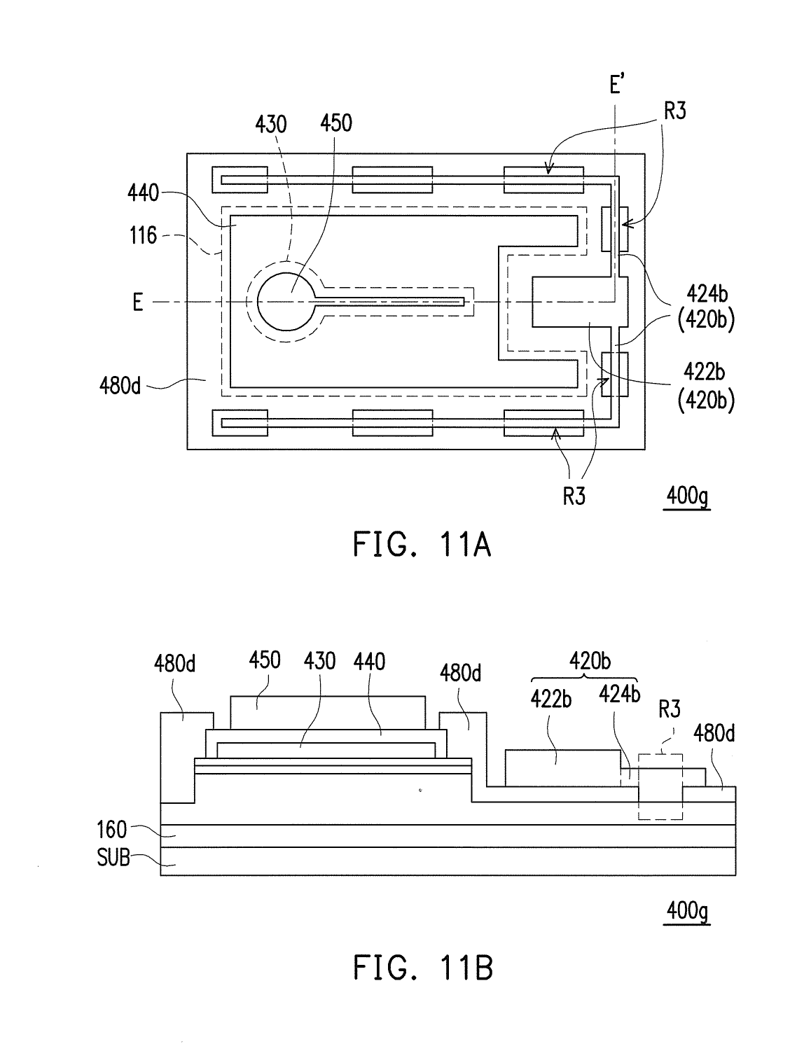

FIG. 11A is a top view of the light-emitting diode chip according to the tenth embodiment of the invention, and FIG. 11B is a cross-sectional view of the light-emitting diode chip of FIG. 11A along line E-E′. Please refer to FIG. 11A and FIG. 11B. In the present embodiment, a light-emitting diode chip 400g is similar to the light-emitting diode chip 400f of the embodiment of FIG. 10A and FIG. 10B. The components of the light-emitting diode chip 400g and relating description are as provided for the light-emitting diode chip 400f of FIG. 10A and FIG. 10B and are not repeated herein. The difference between the light-emitting diode chip 400g and the light-emitting diode chip 400f is that, an insulating layer 480d of the light-emitting diode chip 400g is disposed on the first-type doped semiconductor layer 112, and the portion of the first-type doped semiconductor layer 112 without the insulating layer 480d forms a plurality of regions R3 separated from one another. In the present embodiment, the first electrode 420b of the light-emitting diode chip 400g includes the bonding portion 422b and the branched portions 424b extended from the bonding portion 422b, the branched portions 424b are disposed in the regions R3, and the regions R3 are arranged along the extending direction of the branched portions 424b. Specifically, in some embodiments, a portion of the branched portions 424b disposed in the regions R3 and the insulating layer 480d have a suitable gap. Moreover, the insulating layer 480d covers the second-type doped semiconductor layer 116, the light-emitting layer 114, and a portion of the first-type doped semiconductor layer 112. Therefore, the light-emitting diode chip 400g is not readily short-circuited, and better protection is obtained. In the present embodiment, the insulating layer 480d is disposed between the first electrode 420b and the first-type doped semiconductor layer 112, and the first electrode 420b includes the branched portions 424b extended from the bonding portion 422b. Therefore, the light-emitting diode chip 400g has a similar effect of increasing luminous efficiency to the light-emitting diode chip 400a of the embodiment of FIG. 7A and FIG. 7B. Specifically, since in the locations of the regions R3, the branched portions 424b are in contact with the first-type doped semiconductor layer 112, the regions R3 can be regarded as regions of current collection.

### Eleventh Embodiment

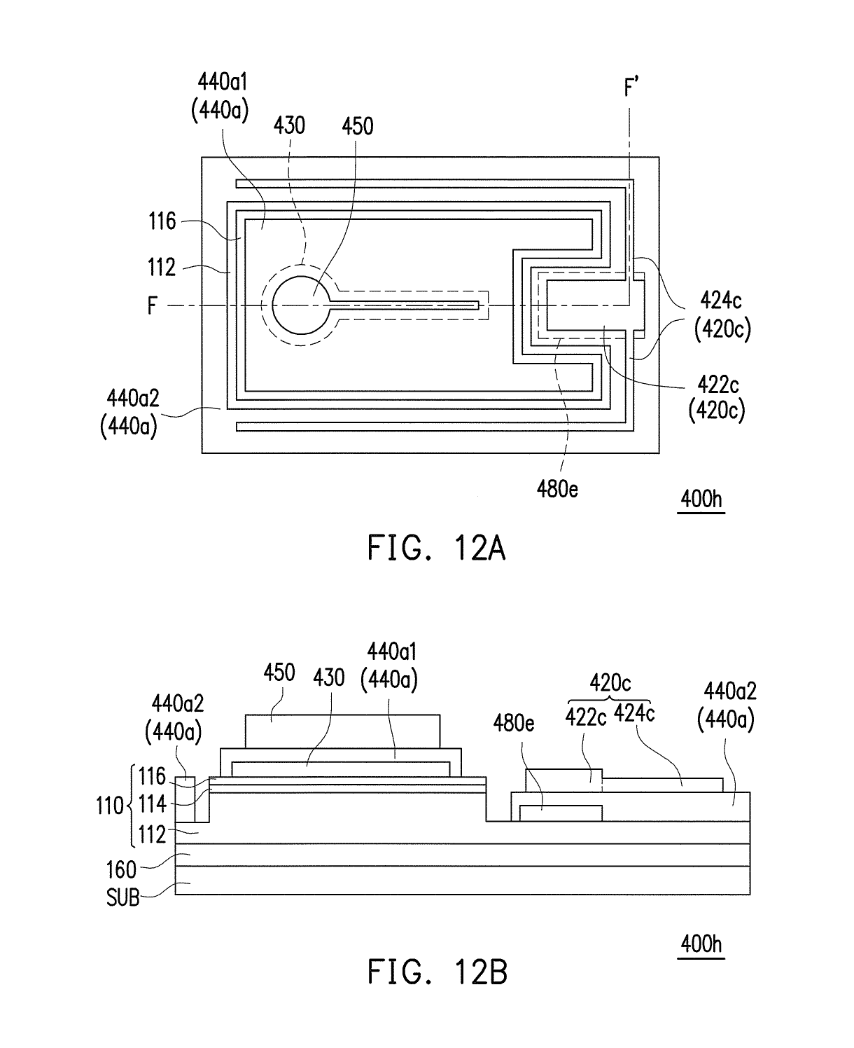

FIG. 12A is a top view of the light-emitting diode chip according to the eleventh embodiment of the invention, and FIG. 12B is a cross-sectional view of the light-emitting diode chip of FIG. 12A along line F-F′. Please refer to FIG. 12A and FIG. 12B. In the present embodiment, a light-emitting diode chip 400h is similar to the light-emitting diode chip 400a of the embodiment of FIG. 7A and FIG. 7B. The components of the light-emitting diode chip 400h and relating description are as provided for the light-emitting diode chip 400a of FIG. 7A and FIG. 7B and are not repeated herein. The difference between the light-emitting diode chip 400h and the light-emitting diode chip 400a is that, a current-spreading layer 440a of the light-emitting diode chip 400h includes a current-spreading layer 440a1 and a current-spreading layer 440a2. The current-spreading layer 440a1 is disposed between the second electrode 450 and the second-type doped semiconductor layer 116, and the current-spreading layer 440a1 covers the current-blocking layer 430. In the present embodiment, the current-spreading layer 440a2 is disposed on the first-type doped semiconductor layer 112 to cover an insulating layer 480e. Moreover, a first electrode 420c includes a bonding portion 422c and branched portions 424c extended from the bonding portion 422c. The bonding portion 422c is disposed above the insulating layer 480e. Specifically, the insulating layer 480e is configured to block electrons from circulating from the bonding portion 422c of the first electrode 420c to a first-type doped semiconductor layer 112c. Therefore, the electrons flow directly from the bonding portion of the first electrode 420c to the current-spreading layer 440a2, or the electrons flow from the bonding portion 422c of the first electrode 420c to the branched portions 424c and then enter the current-spreading layer 440a2. Then, the electrons are circulated to the first-type doped semiconductor layer 112 via the current-spreading layer 440a2. Since the current-spreading layer 440a2 is located between the branched portions 424c and the first-type doped semiconductor layer 112, the region of the first-type doped semiconductor layer 112 receiving the electrons at least includes the region of the first-type doped semiconductor layer 112 corresponding to the branched portions 424c. In the present embodiment, the combination probability of the electrons provided by the first electrode 420c and the electron holes provided by the second electrode 450 is increased to generate more photons, such that the light-emitting diode chip 400h has a similar effect of increasing luminous efficiency to the light-emitting diode chip 400a of the embodiment of FIG. 7A and FIG. 7B.

### Twelfth Embodiment

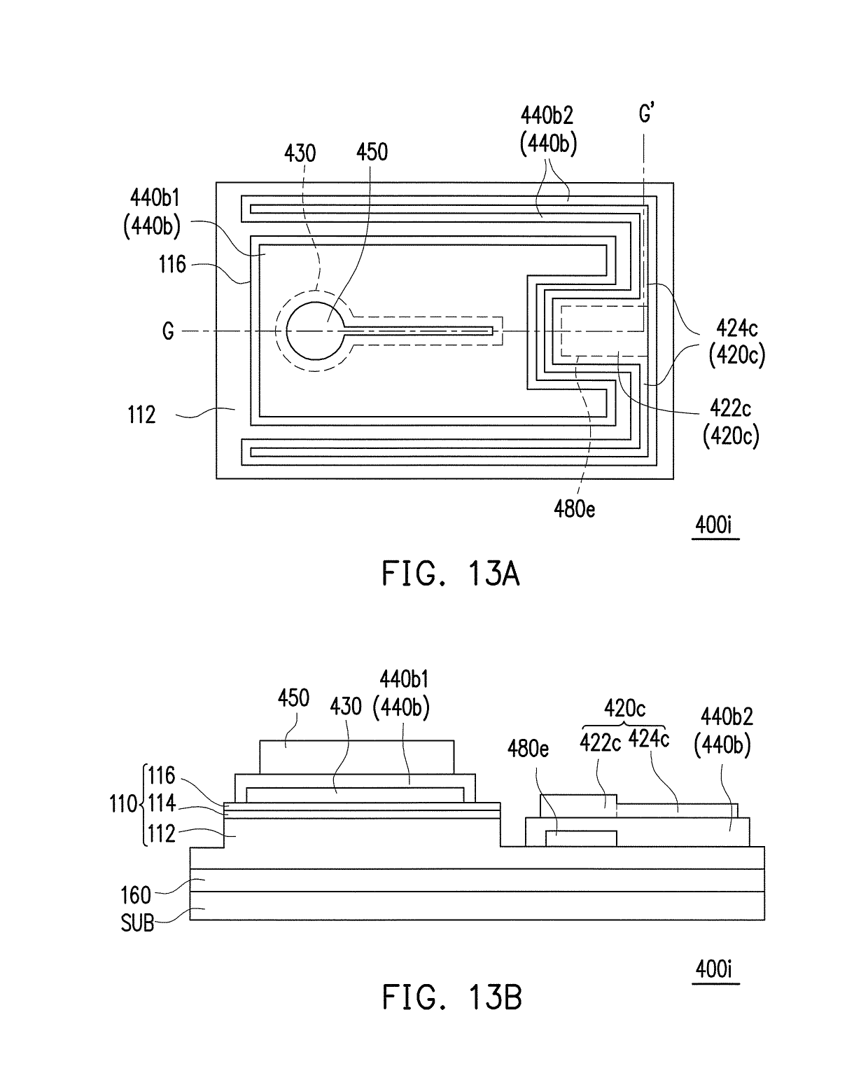

FIG. 13A is a top view of the light-emitting diode chip according to the twelfth embodiment of the invention, and FIG. 13B is a cross-sectional view of the light-emitting diode chip of FIG. 13A along line G-G′. Please refer to FIG. 13A and FIG. 13B. In the present embodiment, a light-emitting diode chip 400i s similar to the light-emitting diode chip 400h of the embodiment of FIG. 12A and FIG. 12B. The components of the light-emitting diode chip 400i and relating description are as provided for the light-emitting diode chip 400h of FIG. 12A and FIG. 12B and are not repeated herein. The difference between the light-emitting diode chip 400i and the light-emitting diode chip 400h is that, the current-spreading layer 440b of the light-emitting diode chip 400i includes a current-spreading layer 440b1 and a current-spreading layer 440b2. The current-spreading layer 440b 1 is disposed between the second electrode 450 and the second-type doped semiconductor layer 116, and the current-spreading layer 440b1 covers the current-blocking layer 430. Moreover, the current-spreading layer 440b2 is disposed on the first-type doped semiconductor layer 112 to cover an insulating layer 480e. In the present embodiment, the current-spreading layer 440b2 is disposed between the branched portions 424c and the first-type doped semiconductor layer 112 along the extending direction of the branched portions 424c, and the disposition range of the current-spreading layer 440b2 on the first-type doped semiconductor layer 112 corresponds to a nearby region of the location of the branched portions 424c. Therefore, the region of the first-type doped semiconductor layer 112 receiving the electrons at least includes the region of the first-type doped semiconductor layer 112 corresponding to the branched portions 424c, such that the light-emitting diode chip 400i has a similar effect of increasing the luminous efficiency to the light-emitting diode chip 400h of the embodiment of FIG. 12A and FIG. 12B.

### Thirteenth Embodiment

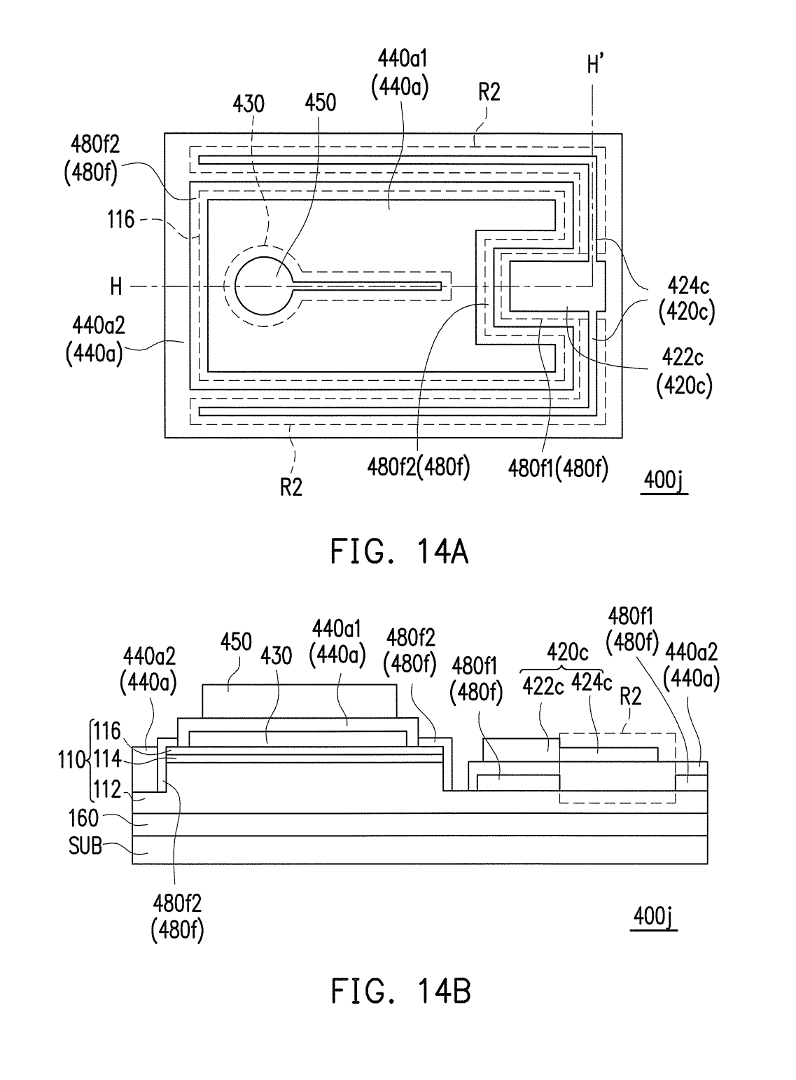

FIG. 14A is a top view of the light-emitting diode chip according to the thirteenth embodiment of the invention, and FIG. 14B is a cross-sectional view of the light-emitting diode chip of FIG. 14A along line H-H′. Please refer to FIG. 14A and FIG. 14B. In the present embodiment, a light-emitting diode chip 400j is similar to the light-emitting diode chip 400h of the embodiment of FIG. 12A and FIG. 12B. The components of the light-emitting diode chip 400j and relating description are as provided for the light-emitting diode chip 400h of FIG. 12A and FIG. 12B and are not repeated herein. The difference between the light-emitting diode chip 400j and the light-emitting diode chip 400h is that, an insulating layer 480f of the light-emitting diode chip 400j includes an insulating layer 480f1 and an insulating layer 480f2, and the current-spreading layer 440a includes the current-spreading layer 440a1 and the current-spreading layer 440a2. The current-spreading layer 440a2 disposed on the first-type doped semiconductor layer 112 to cover the insulating layer 480f1 is a first current-spreading layer, and the current-spreading layer 440a1 disposed on the second-type doped semiconductor layer 116 is a second current-spreading layer. In the present embodiment, the insulating layer 480f2 is disposed between the first current-spreading layer and the second current-spreading layer, and the insulating layer 480f2 electrically insulates the first current-spreading layer and the second current-spreading layer. Specifically, the insulating layer 480f2 is disposed between the current-spreading layer 440a2 and the current-spreading layer 440a1, and the insulating layer 480f2 electrically insulates the current-spreading layer 440a2 and the current-spreading layer 440a1. Therefore, the light-emitting diode chip 400j is not readily short-circuited, and better protection is obtained. In the present embodiment, the current-spreading layer 440a2 is located between the branched portions 424c and the first-type doped semiconductor layer 112, and the insulating layer 480f1 blocks the electrons from the bonding portion 422c from entering the first-type doped semiconductor layer 112. Therefore, the light-emitting diode chip 400j has a similar effect of increasing luminous efficiency to the light-emitting diode chip 400h of the embodiment of FIG. 12A and FIG. 12B.

### Fourteenth Embodiment

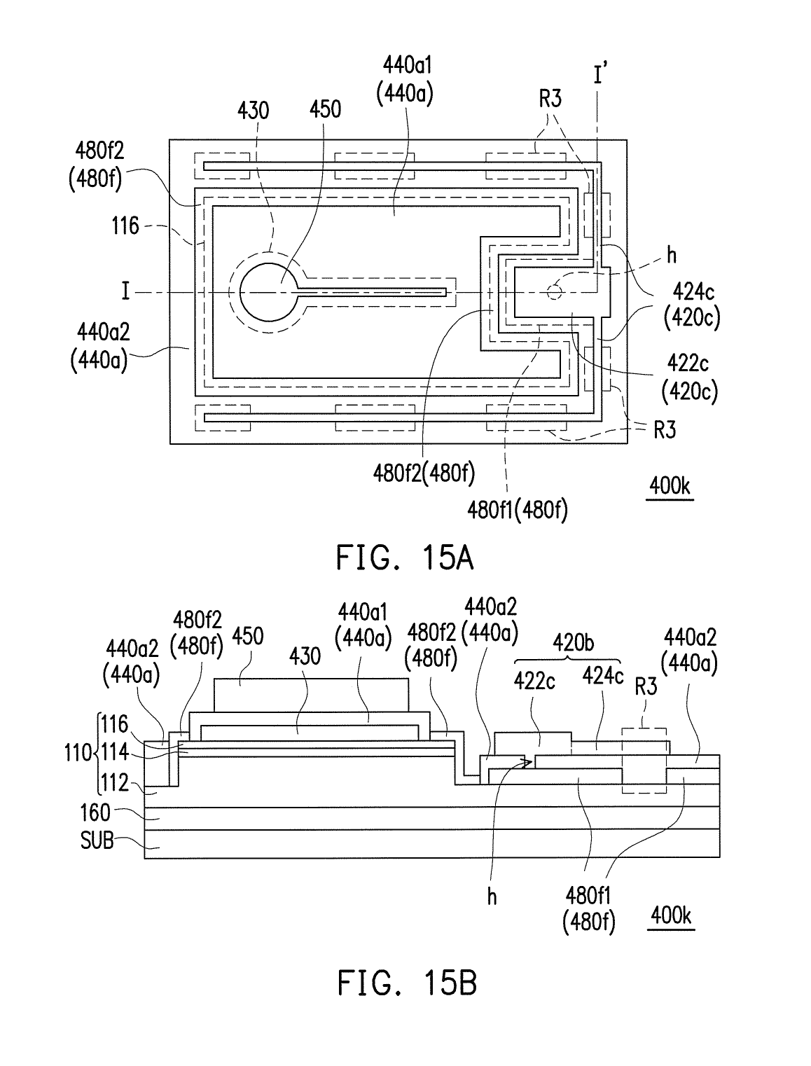

FIG. 15A is a top view of the light-emitting diode chip according to the fourteenth embodiment of the invention, and FIG. 15B is a cross-sectional view of the light-emitting diode chip of FIG. 15A along line I-I′. Please refer to FIG. 15A and FIG. 15B. In the present embodiment, a light-emitting diode chip 400k is similar to the light-emitting diode chip 400j of the embodiment of FIG. 14A and FIG. 14B. The components of the light-emitting diode chip 400k and relating description are as provided for the light-emitting diode chip 400j of FIG. 14A and FIG. 14B and are not repeated herein. The difference between the light-emitting diode chip 400k and the light-emitting diode chip 400j is that, the insulating layer 480f1 of the light-emitting diode chip 400k is disposed on the first-type doped semiconductor layer 112, and the portion of the first-type doped semiconductor layer 112 without the insulating layer 480f1 forms a plurality of regions R3 separated from one another. In the present embodiment, since in the locations of the regions R3, the electrons from the branched portions 424c can be transmitted to the first-type doped semiconductor layer 112 via the current-spreading layer 440a2 in contact therewith, the regions R3 can be regarded as regions of current collection. Moreover, in some embodiments, the current-spreading layer 440a2 below the bonding portion 422c has a hole h. The bonding portion 422c is filled in the hole h and is in contact with the insulating layer 480f1 via the hole h. Specifically, the light-emitting diode chip 400k has a similar effect of increasing luminous efficiency to the light-emitting diode chip 400j of the embodiment of FIG. 14A and FIG. 14B.

### Fifteenth Embodiment

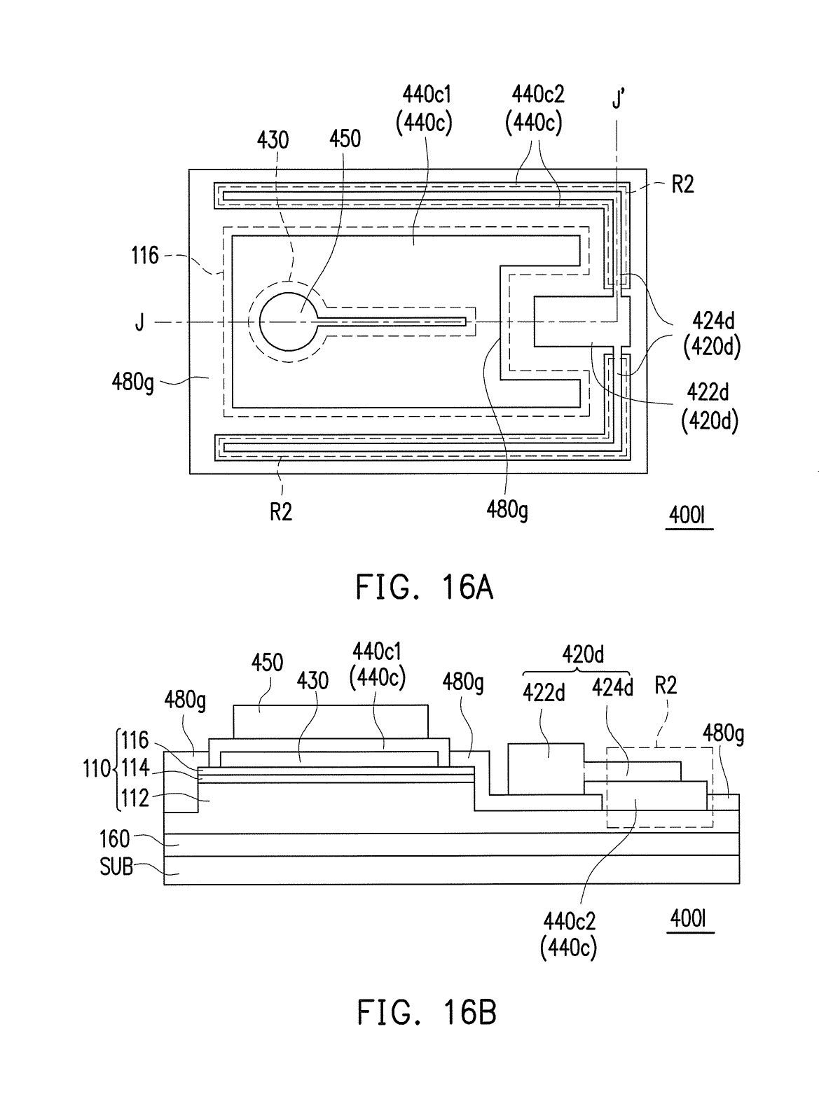

FIG. 16A is a top view of the light-emitting diode chip according to the fifteenth embodiment of the invention, and FIG. 16B is a cross-sectional view of the light-emitting diode chip of FIG. 16A along line J-J′. Please refer to FIG. 16A and FIG. 16B. In the present embodiment, a light-emitting diode chip 400l is similar to the light-emitting diode chip 400f of the embodiment of FIG. 10A and FIG. 10B. The components of the light-emitting diode chip 400l and relating description are as provided for the light-emitting diode chip 400f of FIG. 10A and FIG. 10B and are not repeated herein. The difference between the light-emitting diode chip 400l and the light-emitting diode chip 400f is that, a current-spreading layer 440c of the light-emitting diode chip 400l includes a current-spreading layer 440c1 and a current-spreading layer 440c2, and a first electrode 420d includes a bonding portion 422d and branched portions 424d extended from the bonding portion 422d. The current-spreading layer 440c2 is disposed in the region R2 without an insulating layer 480g, and the current-spreading layer 440c2 is disposed between the branched portions 424d and the first-type doped semiconductor layer 112. In the present embodiment, the insulating layer 480g covers the second-type doped semiconductor layer 116, the light-emitting layer 114, and a portion of the first-type doped semiconductor layer 112. Therefore, the light-emitting diode chip 400l is not readily short-circuited, and better protection is obtained. Moreover, the light-emitting diode chip 400l has a similar effect of increasing luminous efficiency to the light-emitting diode chip 400f of the embodiment of FIG. 10A and FIG. 10B.

### Sixteenth Embodiment

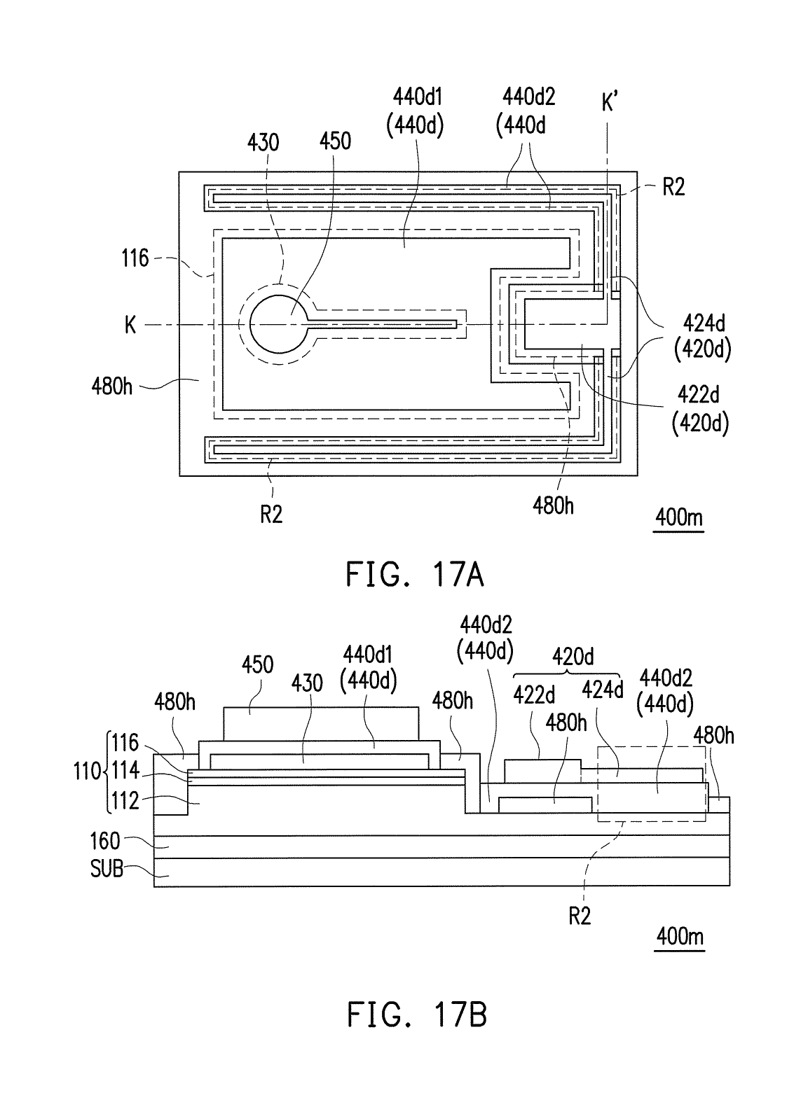

FIG. 17A is a top view of the light-emitting diode chip according to the sixteenth embodiment of the invention, and FIG. 17B is a cross-sectional view of the light-emitting diode chip of FIG. 17A along line K-K′. Please refer to FIG. 17A and FIG. 17B. In the present embodiment, a light-emitting diode chip 400m is similar to the light-emitting diode chip 400l of the embodiment of FIG. 16A and FIG. 16B. The components of the light-emitting diode chip 400m and relating description are as provided for the light-emitting diode chip 400l of FIG. 16A and FIG. 16B and are not repeated herein. The difference between the light-emitting diode chip 400m and the light ting diode chip 400l is that, a current-spreading layer 440d of the light-emitting diode chip 400m includes a current-spreading layer 440d1 and a current-spreading layer 440d2. The current-spreading layer 440d2 is disposed in the region R2 without the insulating layer 480g, and the current-spreading layer 440d2 is disposed between the branched portions 424d and the first-type doped semiconductor layer 112. In the present embodiment, the current-spreading layer 440d2 is also disposed between the bonding portion 422d and an insulating layer 480h, and the current-spreading layer 440d2 covers the insulating layer 480h. Specifically, the light-emitting diode chip 400m has a similar effect of increasing luminous efficiency to the light-emitting diode chip 400l of the embodiment of FIG. 16A and FIG. 16B.

### Seventeenth Embodiment

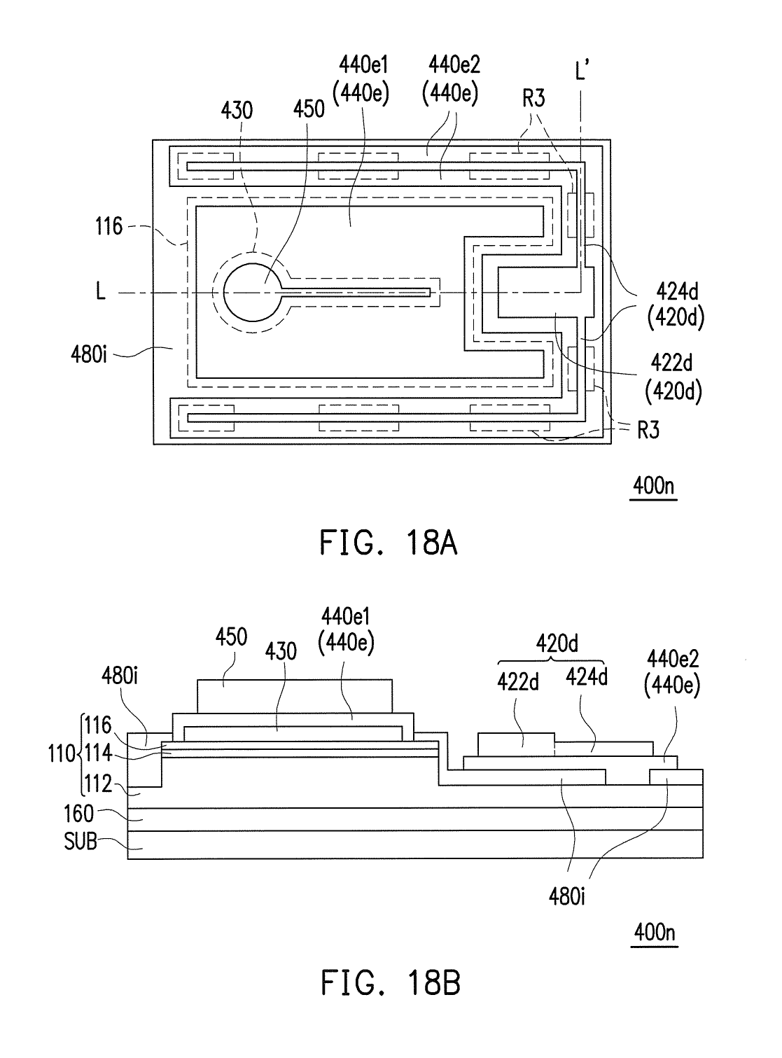

FIG. 18A is a top view of the light-emitting diode chip according to the seventeenth embodiment of the invention, and FIG. 18B is a cross-sectional view of the light-emitting diode chip of FIG. 18A along line L-L′. Please refer to FIG. 18A and FIG. 18B. In the present embodiment, a light-emitting diode chip 400n is similar to the light-emitting diode chip 400m of the embodiment of FIG. 17A and FIG. 17B. The components of the light-emitting diode chip 400n and relating description are as provided for the light-emitting diode chip 400m of FIG. 17A and FIG. 17B and are not repeated herein. The difference between the light-emitting diode chip 400n and the light-emitting diode chip 400m is that, a current-spreading layer 440e of the light-emitting diode chip 400n includes a current-spreading layer 440e1 and a current-spreading layer 440e2. Moreover, an insulating layer 480i of the light-emitting diode chip 400n is disposed on the first-type doped semiconductor layer 112, and the portion of the first-type doped semiconductor layer 112 without the insulating layer 480i forms a plurality of regions R3 separated from one another. In the present embodiment, the first electrode 420d of the light-emitting diode chip 400n includes the bonding portion 422d and the branched portions 424d extended from the bonding portion 422d, the branched portions 424d are disposed in the regions R3, and the regions R3 are arranged along the extending direction of the branched portions 424d. Moreover, in some embodiments, a portion of the branched portions 424d disposed in the regions R3 and the insulating layer 480i have a suitable gap. Specifically, since in the locations of the regions R3, the electrons from the branched portions 424d can be transmitted to the first-type doped semiconductor layer 112 via the current-spreading layer 440e2 in contact therewith, the regions R3 can be regarded as regions of current collection. Specifically, the light-emitting diode chip 400n has a similar effect of increasing luminous efficiency to the light-emitting diode chip 400k of the embodiment of FIG. 15A and FIG. 15B.

Various implementations of the current-blocking layers and the second electrodes of the light-emitting diode chip 100a, the light-emitting diode chip 100b, the light-emitting diode chip 100c, and the light-emitting diode chip 200 can be at least applied in the light-emitting diode chip 300a, the light-emitting diode chip 300c, the light-emitting diode chip 300d, the light-emitting diode chip 400a, the light-emitting diode chip 400c, the light-emitting diode chip 400d, the light-emitting diode chip 400e, the light-emitting diode chip 400f, the light-emitting diode chip 400g, the light-emitting diode chip 400h, the light-emitting diode chip 400i, the light-emitting diode chip 400j, the light-emitting diode chip 400k, the light-emitting diode chip 400l, the light-emitting diode chip 400m, and the light-emitting diode chip 400n of FIG. 4A to FIG. 18B, and the invention is not limited thereto.

Based on the above, since in the embodiments of the invention, a current-blocking layer having a specific pattern design is adopted in the light-emitting diode chip, the light-emitting diode chip of the invention has good luminous efficiency. Moreover, in the embodiments of the invention, the insulating layer is disposed between the first electrode and the first-type doped semiconductor layer to control the location of current collection, and therefore the luminous efficiency of the light-emitting diode chip can be increased.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A light-emitting diode chip, comprising:
a semiconductor device layer comprising a first-type doped semiconductor layer, a light-emitting layer, and a second-type doped semiconductor layer, wherein the light-emitting layer is located between the first-type doped semiconductor layer and the second-type doped semiconductor layer;
a first electrode electrically connected to the first-type doped semiconductor layer;
a current-blocking layer disposed on the second-type doped semiconductor layer, and the current-blocking layer comprises a main body and an extension portion extended from the main body;
a current-spreading layer disposed on the second-type doped semiconductor layer to cover the current-blocking layer; and
a second electrode electrically connected to the second-type doped semiconductor layer via the current-spreading layer, wherein the second electrode comprises a bonding pad and a finger portion extended from the bonding pad, the bonding pad is located above the main body, the finger portion is located above the extension portion, and a partial region of the finger portion does not overlap the extension portion.

2. The light-emitting diode chip of claim 1, wherein the light-emitting layer is disposed on the first-type doped semiconductor layer to expose a portion of the first-type doped semiconductor layer, and the first electrode is disposed on the portion of the first-type doped semiconductor layer exposed by the light-emitting layer.

3. The light-emitting diode chip of claim 1, wherein the extension portion comprises a plurality of current-blocking patterns separated from one another, and the current-blocking patterns are arranged along an extending direction of the finger portion.

4. The light-emitting diode chip of claim 1, wherein the extension portion comprises:
a plurality of current-blocking patterns arranged along an extending direction of the finger portion; and
a plurality of connecting patterns, wherein the current-blocking patterns are connected to one another via the connecting patterns.

5. The light-emitting diode chip of claim 4, wherein the connecting patterns overlap the finger portion, and a width of each of the connecting patterns along the extending direction of the finger portion is less than a width of the finger portion.

6. The light-emitting diode chip of claim 4, wherein the connecting patterns do not overlap the finger portion.

7. A light-emitting diode chip, comprising:
a semiconductor device layer comprising a first-type doped semiconductor layer, a light-emitting layer, and a second-type doped semiconductor layer, wherein the light-emitting layer is located between the first-type doped semiconductor layer and the second-type doped semiconductor layer;
a first electrode electrically connected to the first-type doped semiconductor layer;
a current-blocking layer disposed on the second-type doped semiconductor layer, and the current-blocking layer comprises a main body and an extension portion extended from the main body;
a current-spreading layer disposed on the second-type doped semiconductor layer to cover the current-blocking layer; and
a second electrode electrically connected to the second-type doped semiconductor layer, wherein the second electrode comprises a bonding pad and a finger portion extended from the bonding pad, the finger portion is located above the extension portion, the bonding pad passes through the current-spreading layer and the main body, and the bonding pad is in contact with the second-type doped semiconductor layer.

8. The light-emitting diode chip of claim 7, wherein the light-emitting layer is disposed on the first-type doped semiconductor layer to expose a portion of the first-type doped semiconductor layer, and the first electrode is disposed on the portion of the first-type doped semiconductor layer exposed by the light-emitting layer.

9. The light-emitting diode chip of claim 7, wherein a width of the extension portion varies periodically along an extending direction of the finger portion.

10. The light-emitting diode chip of claim 7, wherein a width of the extension portion varies gradually along an extending direction of the finger portion, and a width of the extension portion is greater closer to the first electrode.

11. The light-emitting diode chip of claim 7, wherein the extension portion comprises:
a plurality of current-blocking patterns arranged along an extending direction of the finger portion; and
a plurality of connecting patterns, wherein the current-blocking patterns are connected to one another via the connecting patterns.

12. The light-emitting diode chip of claim 11, wherein the connecting patterns overlap the finger portion, and a width of each of the connecting patterns along the extending direction of the finger portion is greater than or equal to a width of the finger portion.

13. A light-emitting diode chip, comprising:
a substrate;
a semiconductor device layer comprising a first-type doped semiconductor layer, a light-emitting layer, and a second-type doped semiconductor layer, and the first-type doped semiconductor layer is disposed on the substrate, wherein the light-emitting layer is located between the first-type doped semiconductor layer and the second-type doped semiconductor layer;
a current-spreading layer disposed on the second-type doped semiconductor layer;
a first electrode electrically connected to the first-type doped semiconductor layer;
an insulating layer disposed between the first electrode and the first-type doped semiconductor layer; and
a second electrode electrically connected to the second-type doped semiconductor layer via the current-spreading layer.

14. The light-emitting diode chip of claim 13, wherein the light-emitting layer is disposed on the first-type doped semiconductor layer to expose a portion of the first-type doped semiconductor layer, and the first electrode is disposed on the portion of the first-type doped semiconductor layer exposed by the light-emitting layer.

15. The light-emitting diode chip of claim 13, wherein the first electrode comprises a bonding portion and branched portions extended from the bonding portion, and the bonding portion is disposed above the insulating layer.

16. The light-emitting diode chip of claim 15, wherein the bonding portion covers the insulating layer.

17. The light-emitting diode chip of claim 15, wherein the insulating layer is disposed on the first-type doped semiconductor layer, a portion of the first-type doped semiconductor layer without the insulating layer forms a region, and the branched portions are disposed in the region.

18. The light-emitting diode chip of claim 15, wherein the insulating layer is disposed on the first-type doped semiconductor layer, a portion of the first-type doped semiconductor layer without the insulating layer forms a plurality of regions separated from one another, a portion of the branched portions is disposed in the regions, and the regions are arranged along an extending direction of the branched portions.

19. The light-emitting diode chip of claim 13, wherein the insulating layer is further disposed on the second-type doped semiconductor layer.

20. The light-emitting diode chip of claim 13, wherein the current-spreading layer is further disposed on the first-type doped semiconductor layer to cover the insulating layer.
